(19) United States
(12) Patent Application Publication
(10) Pub. No.: US 2014/0193752 A1
(43) Pub. Date: Jul. 10, 2014

(54) STABILIZED ACID AMPLIFIERS

(71) Applicants: Robert L. Brainard, Albany, NY (US); Brian Cardineau, Beaverton, OR (US)

(72) Inventors: Robert L. Brainard, Albany, NY (US); Brian Cardineau, Beaverton, OR (US)

(73) Assignee: The Research Foundation of State University of New York, Albany, NY (US)

(21) Appl. No.: 14/008,475

(22) PCT Filed: Mar. 28, 2012
(86) PCT No.: PCT/US12/30850

§ 371 Date: Dec. 9, 2013

Related U.S. Application Data
(60) Provisional application No. 61/470,767, filed on Apr. 1, 2011.
(60) Provisional application No. 61/597,883, filed on Feb. 13, 2012.

(51) Int. Cl. G03F 7/027

(52) U.S. Cl. CPC G03F 7/027
USPC 430/283.1; 558/54; 549/373; 549/333; 430/281.1; 430/322

(57) ABSTRACT

There are disclosed sulfonic acid precursor compositions, as are methods of using these compositions in, for example, photolithography. Other embodiments are also disclosed.

### CROSS-REFERENCE TO RELATED APPLICATIONS

This application claims priority from pending U.S. Provisional Patent Applications 61/470,767, filed on Apr. 1, 2011, and 61/597,883, filed on Feb. 13, 2012, the disclosures of which are included by reference herein in their entirety.

### FIELD OF THE INVENTION

The invention relates to compositions and methods for acid amplification in photoresists and other relevant applications.

### BACKGROUND

Photolithography or optical lithography is a process used, inter alia, in semiconductor device fabrication to transfer a pattern from a photomask (sometimes called a reticle) to the surface of a substrate. Such substrates are well known in the art. For example, silicon, silicon dioxide and aluminum-aluminum oxide microelectronic wafers have been employed as substrates. Gallium arsenide, ceramic, quartz and copper substrates are also known. The substrate often includes a metal coating.

Photolithography generally involves a combination of substrate preparation, photoresist application and soft-baking, radiation exposure, development, etching and various other chemical treatments (such as application of thinning agents, edge-bead removal etc.) in repeated steps on an initially flat substrate. In some more recently-developed techniques, a hard-bake step is implemented after exposure and prior to development.

A cycle of a typical silicon lithography procedure begins by applying a layer of photoresist—a material that undergoes a chemical transformation when exposed to radiation (generally but not necessarily visible light, ultraviolet light, electron beam, or ion beam)—to the top of the substrate and drying the photoresist material in place, a step often referred to as “soft baking” of the photoresist, since typically this step is intended to eliminate residual solvents. A transparent plate, called a photomask or shadowmask, which has printed on it areas that are opaque to the radiation to be used as well as areas that are transparent to the radiation, is placed between a radiation source and the layer of photoresist. Those portions of the photoresist layer not covered by the opaque areas of the photomask are then exposed to radiation from the radiation source. Exposure is followed by development. In some cases, exposure is followed by a post-exposure bake (PEB), which precedes the development. Development is a process in which the entire photoresist layer is chemically treated. During development, the exposed and unexposed areas of photoresist undergo different chemical changes, so that one set of areas is removed and the other remains on the substrate. After development, those areas of the top layer of the substrate which are uncovered as a result of the development step are etched away. Finally, the remaining photoresist is removed by an etch or strip process, leaving exposed substrate. When a “positive” photoresist is used, the opaque areas of the photomask correspond to the areas where photoresist will remain upon developing (and hence where the topmost layer of the substrate, such as a layer of conducting metal, will remain at the end of the cycle). “Negative” photoresists result in the opposite—any area that is exposed to radiation will remain after developing, and the masked areas that are not exposed to radiation will be removed upon developing.

The need to make circuits physically smaller has steadily progressed over time, necessitating inter alia the use of light of increasingly shorter wavelengths to enable the formation of these smaller circuits. This in turn has necessitated changes in the materials used as photoresists, since in order to be useful as a photoresist, the material should not absorb light at the wavelength used. For example, phenolic materials which are commonly used for photolithography using light of wavelength 248 nm wavelength are generally not suitable for use as photoresists for light of 193 nm, since these phenolic materials tend to absorb 193 nm light.

At present, it is desired to use light in the extreme UV range (13.5 nm or shorter) for photolithography of circuits having line widths of 32-20 nm. Many of the materials which would be suitable for use as positive photoresists in this range are polymers which contain acidic groups in protected form, such as tert-butoxycarbonyl (t-BOC) protected forms of polymers derived from polyhydroxystyrene or t-butylacrylate polymers. Following the “soft bake” of the photoresist, exposure of the masked photoresist to radiation and, if necessary, post-exposure bake should result in deprotection of polymers in the areas which were not covered by the opaque portions of the mask, thus rendering these areas susceptible to attack by base, to enable the removal of these areas in the development step. In order to achieve this result, it has been proposed to utilize “chemically amplified” photoresists. The idea is to include in the photoresist an amount of a thermally stable, photolytically activated acid precursor (sometimes called a “photoacid generator” or “PAG”), so that upon irradition acid will be generated which can deprotect the irradiated portions of the positive photoresist polymer, rendering them susceptible to base attack.

In a variation on the chemical amplification technique, it has been proposed to include in the resist composition a photoacid generator, as well as an acid precursor (sometimes referred to as an “acid amplifier”) which is (a) photolytically stable and (b) thermally stable in the absence of acid but thermally active in the presence of acid. In such systems, during radiation exposure the PAG generates acid, which then during post-exposure bake acts as a catalyst to activate the acid-amplifier. Such systems are sometimes referred to in the literature as “acid amplifier” systems, since the catalytic action of the photolytically-generated acid on the second acid precursor during post-exposure bake results in an effective number of acid molecules which is higher than the number of photons absorbed during radiation exposure, thus effectively “amplifying” the effect of exposure and amplifying the amount of acid present.

Similarly, the use of PAGs and acid amplifiers in negative resists has been proposed. In these cases, the acid generated makes the areas of resist exposed to radiation less soluble in the developing solvent, usually by either effecting or catalyzing cross-linking of the resist in the exposed areas or by changing the polarity or hydrophilicity/hydrophobicity in the radiation-exposed areas of the resist.

Among the difficulties encountered in trying to implement chemical amplification photoresists systems is “outgassing”, a process whereby, as a result of acid formation, gas is generated, leading to volatile compounds that can leave the resist film while the wafer is still in the exposure tool. Outgassing can occur under ambient conditions or under vacuum as is used with extreme ultraviolet (EUV) lithography. Outgassing is a problem because the small molecules can deposit on the optics (lenses or mirrors) of the exposure tool and cause a diminution of performance. Furthermore, there is a trade-off between resolution, line-width roughness and sensitivity. A resist's resolution is typically characterized as the smallest feature the resist can print. Line width roughness is the statistical variation in the width of a line. Sensitivity is the dose of radiation required to print a specific feature on the resist, and is usually expressed in units of mJ/cm². Moreover, hitherto it has proven difficult to find acid precursors which display the requisite photostability, thermal stability in the absence of acid, and thermal acid-generating ability in the presence of acid, and which generate acids which are sufficiently strong so as to deprotect the protected resins used in photolithography.

Thus, although some acid amplifier systems have been proposed for use in photolithography using 248 nm light, there remains a need for acid amplifier systems which may be used in photolithography, particularly for use in extreme UV (13.5 nm) or electron-beam lithography.

### BRIEF DESCRIPTION OF THE INVENTION

Acid amplifiers (AAs) are subdivided into components: a trigger, a body and an acid precursor. The trigger is an acid sensitive group that, when activated under acid, allows the compound to decompose and release the acid.

AAs can be classified as Generation-1, Generation-2 and Generation-3 based on the acids strength that they generate and their thermal stability. Generation-1 AAs generate weak nonfluorinated acids such as toluenesulfonic acid. Generation-2 AAs generate moderately strong fluorinated sulfonic acids such as p-(trifluoromethyl)-benzenesulfonic acid. Generation-3 AAs generate strong fluorinated sulfonic acids such as triflic acid and the AAs are thermally stable in the absence of catalytic acid. It is also possible to further modify the trigger mechanism to produce acid amplifiers that decompose with slightly higher reactivity at moderate temperatures (90-130° C.) by providing two ethers on the same carbon, or ketal-based triggers. These are referred to as Generation-4 AAs. Examples of the four generations are shown below:

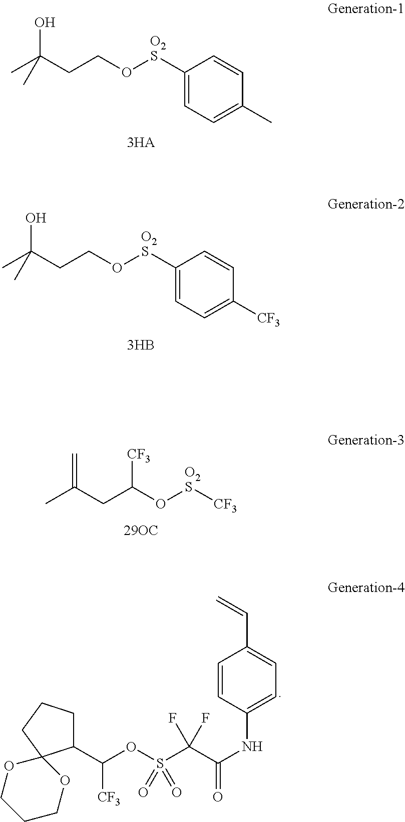

Generation 2 triggers have traditionally consisted of an acid-sensitive leaving group. Upon acidification, this group becomes protonated and causes this compound to eliminate, regenerating the original acid. The product of the elimination results in an olefin which activates the acid precursor to also eliminate. This results in a second acid being generated, and is how the acid signal is amplified, as shown below:

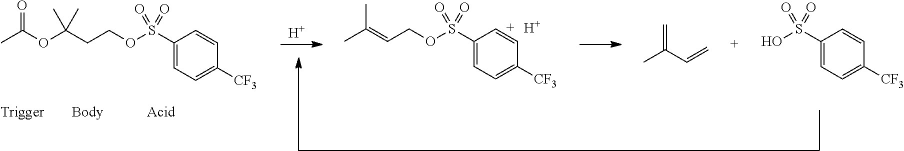

Most acid amplifiers currently have triggers that are leaving groups. The acid activates the trigger; the trigger then leaves, creating a double bond. Since the double bond is allylic to the acid, the compound decomposes thermally producing an acid.

The decomposition of Generation 2 trigger types is energetically favorable in two ways. EUV photoresists utilize very strong acids (pKa˜−10). Since these triggers are generally alcohols and ethers (pKa˜−2 to −4), it is energetically favored for the acid to protonate these groups. Furthermore, the reaction of the trigger activation results in two products; the activated body-acid precursor complex and the removed trigger. This increase in the product stoichiometry is favored by entropy and thus further facilitates the trigger activation. Due to these two reasons, Generation 2 triggers can be activated very easily. However, it has been found that, for EUV photoresists, this trigger type often is too sensitive and may result in overly sensitized acid amplifiers.

To improve the AA acid strength, the AA thermal stability should be increased and decomposition should be minimized. Steric hindrance is the best way to reduce nucleophilic attack. Further, Generation-2 AAs are prone to S_{N}1 decomposition, but reducing the electron density at the C—O sulfonate bond inhibits S_{N}1 reactions. It has been found that, by incorporating a moiety with specific characteristics alpha to the sulfonate ester, decomposition is controlled. Without being bound to the theory, it is believed that this moiety sterically hinders the sulfonate ester from nucleophilic attack and is often highly electron withdrawing to destabilize carbocation formation. Compounds with this new design are known as stabilized Generation-3 AAs.

The reactivity of these compounds may be further modified by altering the trigger mechanism. For example, Generation-4 AAs may be produced by making ketal-based (or thioketal-based) triggers. These ketal-triggered acid amplifiers may then be attached to functional groups that can be incorporated into polymers using free radical polymerization (8-24 hour reactions in refluxing THF). The stability of these acid amplifiers will also allow other polymer attachment reactions.

In some embodiments the sulfonic acid precursor in the photoresist composition is of formula I:

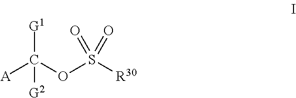

wherein
G¹ is selected from —N⁺(CH₃)₃, —(CH₂)—N⁺(CH₃)₃, —(CH₂)—NO₂, —CH₂(CN), —CH(CN)₂, —(CH₂)₀₋₁SO₂(C₁-C₈)hydrocarbon, —C₆F₅, —Si(CH₃)₃, halogen, —CᵢHⱼ(halogen)ₖ, and CₛHₜ(halogen)ᵤ-E, wherein i is 1-2, j is 0-3, k is 1-5, and the sum of j plus k is 2i+1; and wherein s is 1-2, t is 0-2, u is 1-4, and the sum of t plus u is 2s;
E is selected from —(C₁-C₆)alkyl, aryl, (C₁-C₆)haloalkyl, haloaryl, haloaryl(C₁-C₂)alkyl, and aryl(C₁-C₂)alkyl;
G² is selected from hydrogen, —CF₃, —N⁺(CH₃)₃, halogen and (C₁-C₁₀)hydrocarbon;
A is selected from the following moieties:

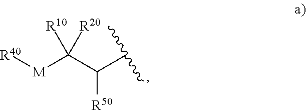

wherein

M is —O—, —S— or —NR⁹⁰—;

R¹⁰ is chosen from (C₁-C₈)saturated hydrocarbon; (C₁-C₈)saturated hydrocarbon substituted with halogen, cyano or nitro; (C₁-C₈)silaalkane; —O—(C₁-C₈)saturated hydrocarbon; —O—(C₁-C₈)saturated hydrocarbon substituted with halogen, cyano or nitro; —S—(C₁-C₈)saturated hydrocarbon; —S—(C₁-C₈)saturated hydrocarbon substituted with halogen, cyano or nitro; and optionally substituted phenyl;

R²⁰ is chosen from H, (C₁-C₆) hydrocarbon and (C₁-C₆) hydrocarbon substituted with nitro or cyano, or taken together with the carbon to which they are attached, R¹⁰ and R²⁰ form a three- to eight-membered ring;

R⁴⁰ is chosen from H, (C₁-C₆)alkyl, —C(═O)(C₁-C₆)alkyl, —C(═O)(C₁-C₆)alkenyl, —C(═O)(C₁-C₆)haloalkyl, benzyl, substituted benzyl, —C(═O)phenyl, —C(═O)substituted phenyl, —SO₂phenyl, —SO₂(substituted)phenyl and Q; or, when M is O or S, R¹⁰ and R⁴⁰ together with the carbons to which they are attached form a four- to eight-membered ring optionally substituted with one or more (C₁-C₆) hydrocarbon groups;

R⁵⁰ is chosen from H, (C₁-C₆) hydrocarbon, nitro, cyano, (C₁-C₆) hydrocarbon substituted with nitro or cyano, and (C₁-C₆)silaalkane, or together with the carbons to which they are attached, R¹⁰ and R⁵⁰ form a (C₃-C₈) hydrocarbon ring; or, when M is O or S, R²⁰ and R⁵⁰ together with the carbons to which they are attached form a three- to eight-membered ring optionally substituted with one or more (C₁-C₆) hydrocarbon groups;

R⁹⁰ is chosen from H, (C₁-C₆)alkyl, —C(═O)(C₁-C₆)alkyl and phenyl, or or together with the nitrogen to which they are attached, R⁴⁰ and R⁹⁰ may form a nitrogen heterocycle, with the proviso that one of R⁴⁰ and R⁹⁰ must be an acyl, and when R⁴⁰ and R⁹⁰ together with the nitrogen to which they are attached form a heterocycle, the heterocyle must contain one or two α-oxo substituents; and

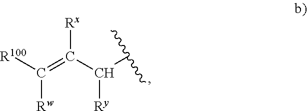

wherein

R^{w}, R^{x} and R^{y} are chosen independently in each instance from hydrogen, (C₁-C₈)silaalkane and (C₁-C₁₀) hydrocarbon;

R¹⁰⁰ is chosen from hydrogen and (C₁-C₂₀) hydrocarbon; or

any two of R¹⁰⁰, R^{w}, R^{x}, R^{y} and G², taken together with the carbons to which they are attached, form a (C₅-C₈) hydrocarbon ring which may be substituted with (C₁-C₈)hydrocarbon,
with the proviso that the C═C double bond above is not contained within a phenyl ring; or

G¹ and A, together with the carbon to which they are attached, can form a non-aromatic, 5- or 6-membered ring D:

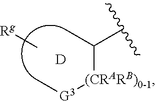

wherein R^{g} represents one or two substituents independently selected in each instance from hydrogen, -M-R⁴⁰, (C₁-C₁₀)hydrocarbon, hydroxyl and R^{h}CH₂COO—, wherein R^{h} is chosen from halogen, hydroxyl, a polymer and an oligomer; and wherein G³ is selected from —N⁺(CH₃)₂, —(CH)—NO₂, —CH(CN), —C(CN)₂, —Si(CH₃)₂—, —CᵢHⱼ(halogen)ₖ, and CₛHₜ(halogen)ᵤ-E, wherein i is 1-2, j is 0-3, k is 1-5, and the sum of j plus k is 2i; and wherein s is 1-2, t is 0-2, u is 1-4, and the sum of t plus u is 2s minus 1; and wherein R^{A} and R^{B} can each be selected independently from hydrogen, (C₁-C₆)alkyl and benzyl;

R³⁰ is chosen from
(a) —CₙHₘFₚ wherein n is 1-8, m is 0-16, p is 1-17 and the sum of m plus p is 2n+1;
(b) —CH₂C(═O)-Q;
(c) —CF₂CH₂OQ;
(d) —CF₂C(═O)-Q;
(e) —CF₂CH₂OC(═O)—R³¹, wherein R³¹ is selected from CH═CH₂, CCH₃═CH₂, CHQCH₂Q and CCH₃QCH₂Q;

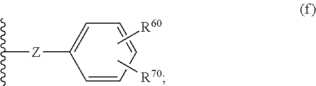

wherein Z is a direct bond, CH₂, CHF or CF₂;

R⁶⁰ is chosen from —CF₃, —OCH₃, —NO₂, F, Cl, Br, —CH₂Br, —CH═CH₂, —OCH₂CH₂Br, -Q, —CH₂-Q, —O-Q, —OCH₂CH₂-Q, —OCH₂CH₂O-Q, —CH(O)CH₂-Q, —OC═OCH═CH₂, —OC═OCCH₃═CH₂, —OC═OCHQCH₂Q, and —OC═OCCH₃QCH₂Q;

R⁷⁰ represents from one to four substituents chosen independently in each instance from H, —CF₃, —OCH₃, —CH₃, —NO₂, F, Br, Cl, —CᵢHⱼ(halogen)ₖ, and CₛHₜ(halogen)ᵤ-E, wherein i is 1-2, j is 0-3, k is 1-5, and the sum of j plus k is 2i+1; and wherein s is 1-2, t is 0-2, u is 1-4, and the sum of t plus u is 2s;

E is selected from —(C₁-C₆)alkyl, aryl, (C₁-C₆)haloalkyl, haloaryl, haloaryl(C₁-C₂)alkyl, and aryl(C₁-C₂)alkyl;
(g) —(CH₂)_{q}Cl, wherein q is an integer from 1 to 8;
(h) —CF₂C(═O)NHC₆H₄R⁶⁰;
(i) —CH₂C(═O)NHC₆H₄R⁶⁰; and
(j) —CHFC(═O)NHC₆H₄R⁶⁰; and

Q is a polymer or oligomer.

In some embodiments, the invention relates to compounds of formula

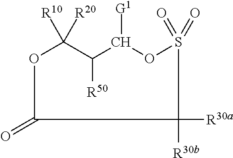

wherein

G¹ is selected from —N⁺(CH₃)₃, —(CH₂)—N⁺(CH₃)₃, —(CH₂)—NO₂, —CH₂(CN), —CH(CN)₂, —(CH₂)₀₋₁SO₂(C₁-C₈)hydrocarbon, —C₆F₅, —Si(CH₃)₃, halogen, —CᵢHⱼ(halogen)ₖ, and CₛHₜ(halogen)ᵤ-E, wherein i is 1-2, j is 0-3, k is 1-5, and the sum of j plus k is 2i+1; and wherein s is 1-2, t is 0-2, u is 1-4, and the sum of t plus u is 2s;

E is selected from —(C₁-C₆)alkyl, aryl, (C₁-C₆)haloalkyl, haloaryl, haloaryl(C₁-C₂)alkyl, and aryl(C₁-C₂)alkyl;

R¹⁰ is chosen from (C₁-C₈)saturated hydrocarbon; (C₁-C₈)saturated hydrocarbon substituted with halogen, cyano or nitro; (C₁-C₈)silaalkane and optionally substituted phenyl;

R²⁰ is chosen from H, (C₁-C₆) hydrocarbon and (C₁-C₆) hydrocarbon substituted with nitro or cyano, or taken together with the carbon to which they are attached, R¹⁰ and R²⁰ form a (C₃-C₈) hydrocarbon ring;

R⁵⁰ is chosen from H, (C₁-C₆) hydrocarbon, nitro, cyano, (C₁-C₆) hydrocarbon substituted with nitro or cyano, and (C₁-C₆)silaalkane, or together with the carbons to which they are attached, R¹⁰ and R⁵⁰ form a (C₃-C₈) hydrocarbon ring;

R^{30a} is chosen from H, F and (C₁-C₆) hydrocarbon; and

R^{30b} is chosen from H and F.

All of the compounds falling within the foregoing parent genera and their subgenera are useful for photolithography. It may be found upon examination that compounds that have been included in the claims are not patentable to the inventors in this application. In this event, subsequent exclusions of species from the compass of applicants' claims are to be considered artifacts of patent prosecution and not reflective of the inventors' concept or description of their invention; the invention encompasses all of the members of the three genera described above that are not already in the possession of the public. The invention also encompasses the use of a broader genus of compounds in photoresists.

Most, but not all, of the acid amplifiers disclosed herein are novel, and thus, there are provided in some embodiments of the invention, the molecules per se, as well as methods for preparing these molecules. In this aspect the invention relates to compounds of the formulae pictured below:

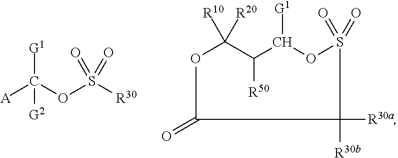

whose definitions are shown above.

In some embodiments, the invention relates to a composition for photolithography comprising a photolithographic polymer and a compound of the formula described above.

In some embodiments, the invention relates to a photoresist composition comprising a photolithographic polymer and a compound of the formula described above. In some embodiments, the photoresist composition is suitable for preparing a positive photoresist. In some embodiments, the photoresist composition is suitable for preparing a negative photoresist. In some embodiments, the photoresist composition is suitable for preparing a photoresist using 248 nm, 193 nm, 13.5 nm light, or using electron-beam or ion-beam radiation.

There is also provided, in accordance with some embodiments of the invention, a photoresist substrate which is coated with a photoresist composition in accordance with embodiments of the invention. In some embodiments, the photoresist substrate comprises a conducting layer upon which the photoresist composition is coated.

There is also provided, in accordance with embodiments of the invention, a method for preparing a substrate for photolithography, comprising coating said substrate with a photoresist composition according to embodiments of the invention.

There is also provided, in accordance with embodiments of the invention, a method for etching conducting photolithography on a substrate, comprising (a) providing a substrate, (b) coating said substrate with a photoresist composition according to embodiments of the invention, and (c) irradiating the coated substrate through a photomask.

In some embodiments, the process of coating comprises applying the photoresist composition to the substrate and baking the applied photoresist composition on the substrate.

In some embodiments, the irradiating is conducted using radiation of sufficient energy and for a sufficient duration to effect the generation of acid in the portions of the photoresist composition which has been coated on said substrate which are exposed to the radiation. For instance, said irradiation is conducted using electromagnetic radiation of wavelength 248 nm, 193 nm, 13.5 nm, or radiation from electron or ion beams.

In some embodiments, the method further comprises after the irradiating but before the developing, baking the coated substrate. In some embodiments, the baking is conducted at a temperature and for a time sufficient for the sulfonic acid precursor in the photoresist coating to generate sulfonic acid.

### BRIEF DESCRIPTION OF THE DRAWINGS

FIG. 1 illustrates thermally-programmed spectroscopic ellipsometry showing that embodiments of the invention are more thermally stable than the resist ESCAP polymer.

FIG. 2 shows SEM images of OS2 resist with 0, 70, 140 and 280 mM of an embodiment of the invention added. Images are 50 nm dense lines and spaces.

FIG. 3 illustrates thermal decomposition of embodiments of the invention: A) With added base and B) In the absence of base.

### DETAILED DESCRIPTION

Substituents are generally defined when introduced and retain that definition throughout the specification and in all independent claims.

The invention relates to compounds of formula I:

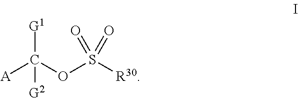

In some embodiments, A is

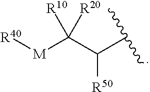

In other embodiments, A is

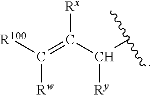

In still other embodiments, G¹ and A, together with the carbon to which they are attached, can form a non-aromatic, 5- or 6-membered ring D:

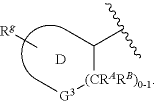

In some embodiments of the invention, D is a saturated 5- or 6-membered ring. In other embodiments, D is an unsaturated 5- or 6-membered ring.

In some embodiments, G¹ is —N⁺(CH₃)₃. In some embodiments, G¹ is —(CH₂)—N⁺(CH₃)₃. In other embodiments, G¹ is —(CH₂)—NO₂. In other embodiments, G¹ is C₆F₅. In other embodiments, G¹ is —CH₂(CN) or —CH(CN)₂. In some embodiments, G¹ is —(CH₂)₀₋₁SO₂(C₁-C₈)hydrocarbon. For instance, in some embodiments G¹ can be —SO₂(CH₃) or —(CH₂)SO₂-benzyl. In still other embodiments, G¹ is —Si(CH₃)₃. In yet other embodiments, G¹ is halogen. In some embodiments, G¹ is —CᵢHⱼ(halogen)ₖ, wherein i is 1-2, j is 0-3, k is 1-5, and the sum of j plus k is 2i+1. As an example, in these embodiments, G¹ could be —CHF₂ or —CF₃. In some embodiments, G¹ is CₛHₜ(halogen)ᵤ-E, wherein s is 1-2, t is 0-2, u is 1-4, and the sum of t plus u is 2s. As an example, in these embodiments, G¹ could be —C₂H₂F₂-E.

In some embodiments, E is —(C₁-C₆)alkyl or (C₁-C₆)haloalkyl. In other embodiments, E is aryl or haloaryl. In still other embodiments, E is haloaryl(C₁-C₂)alkyl or aryl(C₁-C₂)alkyl.

In some embodiments, G² is hydrogen. In some embodiments, G² is —CF₃. In some embodiments, G² is —N⁺(CH₃)₃. In some embodiments, G² is halogen. In some embodiments, G² is (C₁-C₁₀)hydrocarbon. For instance, in some embodiments, G² is chosen from (C₁-C₁₀)alkyl, (C₂-C₁₀)alkenyl, and a saturated or unsaturated cyclic (C₄-C₈)hydrocarbon optionally linked by a methylene.

In certain embodiments, M is oxygen. In certain embodiments, M is —NR⁹⁰—. In certain embodiments, M is sulfur.

In some embodiments, R⁹⁰ is hydrogen. In some embodiments, R⁹⁰ is (C₁-C₆)alkyl. In some embodiments, R⁹⁰ is —C(═O)(C₁-C₆)alkyl. In some embodiments, R⁹⁰ is phenyl.

In certain embodiments, R¹⁰ is (C₁-C₈)saturated hydrocarbon. In certain embodiments, R¹⁰ is (C₁-C₈)saturated hydrocarbon substituted with halogen, cyano or nitro. In certain embodiments, R¹⁰ is (C₁-C₈)silaalkane. In some embodiments, R¹⁰ is —O—(C₁-C₈)saturated hydrocarbon. In some embodiments, R¹⁰ is —O—(C₁-C₈)saturated hydrocarbon substituted with halogen, cyano or nitro. In some embodiments, R¹⁰ is −S—(C₁-C₈)saturated hydrocarbon. In some embodiments, R¹⁰ is —S—(C₁-C₈)saturated hydrocarbon substituted with halogen, cyano or nitro. In certain embodiments, R¹⁰ is optionally substituted phenyl. In certain embodiments, R¹⁰ is selected from methyl, propenyl, propynyl, dimethylbutynyl, cyclopropyl, trimethylsilylmethyl, phenyl, nitrophenyl, nitromethyl, and cyanomethyl.

In some embodiments, R²⁰ is chosen from hydrogen, (C₁-C₆) hydrocarbon and (C₁-C₆) hydrocarbon substituted with nitro or cyano. In some embodiments, R²⁰ is hydrogen. In other embodiments, R²⁰ is methyl.

In some embodiments, taken together with the carbon to which they are attached, R¹⁰ and R²⁰ form a three- to eight-membered ring. In some embodiments, R¹⁰ and R²⁰ taken together form a cyclobutyl, cyclopentyl or cyclohexyl ring.

In certain embodiments, R⁵⁰ is chosen from H, (C₁-C₆) hydrocarbon, nitro, cyano, (C₁-C₆) hydrocarbon substituted with nitro or cyano, and (C₁-C₆)silaalkane. In some embodiments, R⁵⁰ is H. In some embodiments, R⁵⁰ is NO₂. In some embodiments, R⁵⁰ is CN. In some embodiments, R⁵⁰ is SiMe₃. In some embodiments, R⁵⁰ is methyl. In some embodiments, R⁵⁰ is phenyl.

In some embodiments, together with the carbons to which they are attached, R¹⁰ and R⁵⁰ form a (C₃-C₈) hydrocarbon ring. In other embodiments, R¹⁰ and R⁵⁰ taken together form a cyclopentyl or cyclohexyl ring. In some embodiments when M is O or S, R²⁰ and R⁵⁰ together with the carbons to which they are attached form a three- to eight-membered ring optionally substituted with one or more (C₁-C₆) hydrocarbon groups.

In some embodiments, R⁴⁰ is chosen from H, (C₁-C₆)alkyl, —C(═O)(C₁-C₆)alkyl, —C(═O)(C₁-C₆)alkenyl, —C(═O)(C₁-C₆)haloalkyl, benzyl, substituted benzyl, —C(═O)phenyl, —C(═O)substituted phenyl, —SO₂phenyl and —SO₂(substituted)phenyl. In other embodiments, R⁴⁰ can be Q. In certain embodiments, R⁴⁰ is chosen from H, methyl, ethyl, isopropyl, t-butyl, benzyl, acetyl, chloroacetyl, dichloroacetyl, trichloroacetyl, benzoyl, 4-(trifluoromethyl)benzoyl, 4-nitrobenzoyl, 4-carboxybenzoyl, 4-methoxybenzoyl, benzenesulfonyl, 4-(trifluoromethyl)benzenesulfonyl, 4-nitrobenzenesulfonyl, 4-carboxybenzenesulfonyl and 4-methoxybenzenesulfonyl.

In some embodiments when M is O or S, R¹⁰ and R⁴⁰ together with the carbons to which they are attached form a four- to eight-membered ring optionally substituted with one or more (C₁-C₆) hydrocarbon groups. In some embodiments, the ring formed by R¹⁰ and R⁴⁰ is

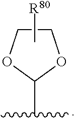

In other embodiments, the ring formed by R¹⁰ and R⁴⁰ is

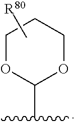

In some embodiments, R⁸⁰ may be hydrogen or one or more (C₁-C₆) hydrocarbon groups in each instance. To be perfectly clear, as one example, R⁸⁰ may be methyl at one position and ethyl at another position, or may be hydrogen in all postions, or may be methyl at two positions. In some embodiments, R⁴⁰ and R⁹⁰, together with the nitrogen to which they are attached, may form a nitrogen heterocycle containing one or two α-oxo substituents. In other embodiments, one of R⁴⁰ and R⁹⁰ must be an acyl.

In certain embodiments, M is oxygen and R⁴⁰ is chosen from H, methyl, ethyl, isopropyl, t-butyl, benzyl, acetyl, chloroacetyl, dichloroacetyl, trichloroacetyl, benzoyl, 4-(trifluoromethyl)benzoyl, 4-nitrobenzoyl, 4-carboxybenzoyl, 4-methoxybenzoyl, benzenesulfonyl, 4-(trifluoromethyl)benzenesulfonyl, 4-nitrobenzenesulfonyl, 4-carboxybenzenesulfonyl and 4-methoxybenzenesulfonyl.

In certain embodiments, M is —NR⁹⁰—. In these embodiments, R⁴⁰ may be chosen from H, methyl, ethyl, isopropyl, t-butyl and benzyl. In some embodiments, R⁹⁰ may be acetyl. In other embodiments, R⁴⁰ and R⁹⁰ together with the nitrogen to which they are attached form a pyrrolidone, phthalimide, maleimide or succinimide ring.

In certain embodiments, M is sulfur and R⁴⁰ is chosen from H, methyl, ethyl, isopropyl, t-butyl, benzyl, acetyl, chloroacetyl, dichloroacetyl, trichloroacetyl, benzoyl, 4-(trifluoromethyl)benzoyl, 4-nitrobenzoyl, 4-carboxybenzoyl and 4-methoxybenzoyl.

In some embodiments, R^{w}, R^{x} and R^{y} are chosen independently in each instance from hydrogen, (C₁-C₈)silaalkane and (C₁-C₁₀)hydrocarbon. In some embodiments, R^{w}, R^{x} and R^{y} are chosen independently in each instance from hydrogen, (C₁-C₁₀)alkyl, (C₂-C₁₀)alkenyl, and a saturated or unsaturated cyclic (C₄-C₈)hydrocarbon optionally linked by a methylene. In some embodiments, R^{y} is hydrogen or (C₁-C₇)hydrocarbon. In other embodiments, R^{y} is hydrogen, methyl, ethyl, propyl, butyl, phenyl and benzyl. In some embodiments, R^{x} is selected from a group that would stabilize a cation formed on the carbon to which R^{x} is attached. For instance, R^{x} may be chosen from phenyl, alkene, alkyne, cyclopropyl and —CH₂Si(CH₃)₃.

In certain embodiments, R¹⁰⁰ is chosen from hydrogen and (C₁-C₂₀) hydrocarbon. In some embodiments, R¹⁰⁰ is chosen from hydrogen, (C₁-C₁₀)alkyl, (C₂-C₁₀)alkenyl, and a saturated or unsaturated cyclic (C₄-C₆)hydrocarbon optionally linked by a methylene. In some embodiments, R¹⁰⁰ is chosen from H, methyl, ethyl, propyl, butyl, phenyl and benzyl. In other embodiments, R¹⁰⁰ is chosen from H, methyl, ethyl, isopropyl, t-butyl, phenyl and benzyl.

In some embodiments, any two of R¹⁰⁰, R^{w}, R^{x}, R^{y} and G², taken together with the carbons to which they are attached, form a (C₅-C₈) hydrocarbon ring which may be substituted with (C₁-C₈)hydrocarbon. In some embodiments, any two of R¹⁰⁰, R^{w}, R^{x}, R^{y} and G², taken together with the carbons to which they are attached, form a cyclopentyl or cyclohexyl ring. In some embodiments, R^{y} and G² taken together form a cyclopentyl or cyclohexyl ring, each of which may be optionally substituted by (C₁-C₈)alkyl. In other embodiments, R^{x} and G² taken together form a cyclopentyl or cyclohexyl ring, each of which may be optionally substituted by (C₁-C₈)alkyl.

In some aspects of the invention, the conjugation in the substituents around the C═C double bond of the skeleton can be balanced. For instance, if R¹⁰⁰ or R^{w} is an aryl group, then it would be advantageous that R^{y} should also be an aryl group. By doing so, the isomerization of the C═C double bond can occur without moving out of conjugation.

In some embodiments, R³⁰ is —CₙHₘFₚ wherein n is 1-8, m is 0-16, p is 1-17 and the sum of m plus p is 2n+1. In certain embodiments, R³⁰ is —CₙF₂ₙ₊₁ or —CH₂CF₃. In other embodiments, R³⁰ is —CH₂C(═O)-Q. In some embodiments, R³⁰ is —CF₂CH₂OQ. In some embodiments, R³⁰ is —CF₂C(═O)-Q. In other embodiments, R³⁰ is —CF₂CH₂C(═O)—R³¹, wherein R³¹ is selected from CH═CH₂, CCH₃═CH₂, CHQCH₂Q and CCH₃QCH₂Q. In certain embodiments, R³⁰ is

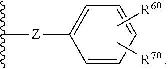

For instance, in some embodiments, R³⁰ is selected from

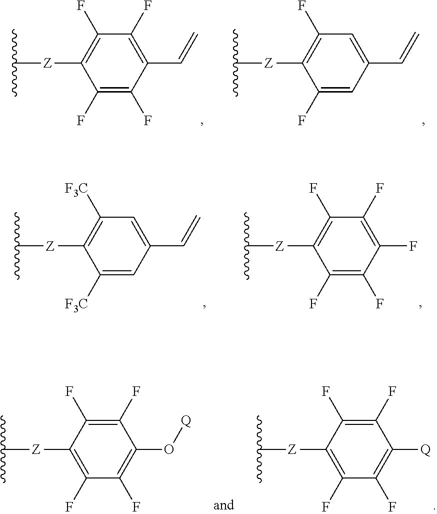

In still other embodiments, R³⁰ is —(CH₂)_{q}Cl, wherein q is an integer from 1 to 8. In other embodiments, R³⁰ is —CF₂C(═O)NHC₆H₄R⁶⁰. In still other embodiments, R³⁰ is —CH₂C(═O)NHC₆H₄R⁶⁰. In other embodiments, R³⁰ is —CHFC(═O)NHC₆H₄R⁶⁰.

In some embodiments, Z is a direct bond. In other embodiments, Z is CH₂. In still other embodiments, Z is CF₂. In still other embodiments, Z is CHF.

In certain embodiments, R⁶⁰ is chosen from —CF₃, —OCH₃, —NO₂, F, Cl, Br, —CH₂Br, —CH═CH₂, —OCH₂CH₂Br, -Q, —CH₂-Q, —O-Q, —OCH₂CH₂-Q, —OCH₂CH₂O-Q, —CH(O)CH₂-Q, —OC═OCH═CH₂, —OC═OCCH₃═CH₂, —OC═OCHQCH₂Q, and —OC═OCCH₃QCH₂Q. In certain embodiments, R⁶⁰ is CF₃. In other embodiments, R⁶⁰ is chosen from —CH₂Br, —CH═CH₂, and —OCH₂CH₂Br. In still other embodiments, R⁶⁰ is chosen from —CH₂-Q, —O-Q, —OCH₂CH₂-Q, —OCH₂CH₂O-Q and —CH(O)CH₂-Q.

In some embodiments, R⁷⁰ represents from one to four substituents chosen independently in each instance from H, —CF₃, —OCH₃, —CH₃, —NO₂, F, Br, Cl, —CᵢHⱼ(halogen)ₖ, and —CₛHₜ(halogen)ᵤ-E, wherein i is 1-2, j is 0-3, k is 1-5, and the sum of j plus k is 2i+1; and wherein s is 1-2, t is 0-2, u is 1-4, and the sum of t plus u is 2s. For instance, R⁷⁰ may represent —CHF-E. In some embodiments, R⁷⁰ represents —CF₃.

In some embodiments, Q is a polymer or an oligomer. Some suitable polymers and oligomers and the means of attachment of residues described herein to those polymers are exemplified in U.S. patent application Ser. No. 12/708,958, the relevant portions of which are incorporated herein by reference.

In some embodiments, R^{g} represents one or two substituents independently selected in each instance from hydrogen, -M-R⁴⁰, (C₁-C₁₀)hydrocarbon, hydroxyl and R^{h}CH₂COO—, wherein R^{h} is chosen from halogen, hydroxyl, a polymer and an oligomer. In certain embodiments, R^{g} is selected independently in each instance from hydrogen and (C₁-C₁₀)hydrocarbon. In other embodiments, R^{g} is selected from hydrogen, methyl and vinyl. In some embodiments, R^{g} is -M-R⁴⁰.

In some embodiments, R^{A} is hydrogen. In some embodiments, R^{A} is (C₁-C₆)alkyl. In some embodiments, R^{A} is benzyl. In some embodiments, R^{B} is hydrogen. In some embodiments, R^{B} is (C₁-C₆)alkyl. In some embodiments, R^{B} is benzyl. In some embodiments, both R^{A} and R^{B} are hydrogen.

In some embodiments, G³ is selected from —N⁺(CH₃)₂, —(CH)—NO₂, —CH(CN), —C(CN)₂, —Si(CH₃)₂—(CH₂)—, —CᵢHⱼ(halogen)ₖ, and CₛHₜ(halogen)ᵤ-E, wherein i is 1-2, j is 0-3, k is 1-5, and the sum of j plus k is 2i; and wherein s is 1-2, t is 0-2, u is 1-4, and the sum of t plus u is 2s minus 1. In certain embodiments, G³ is —N⁺(CH₃)₂.

In some embodiments, G¹ is —CF₃ and R³⁰ is

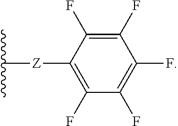

In some embodiments, the invention relates to compounds selected from the group below:

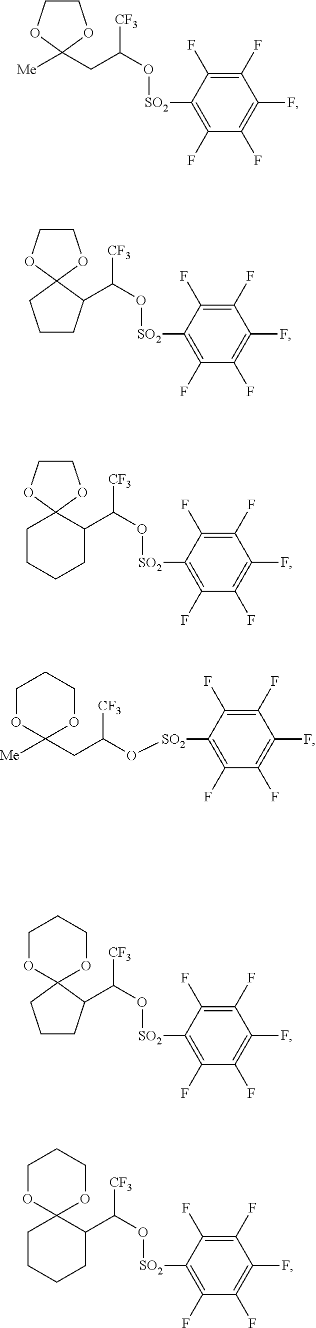

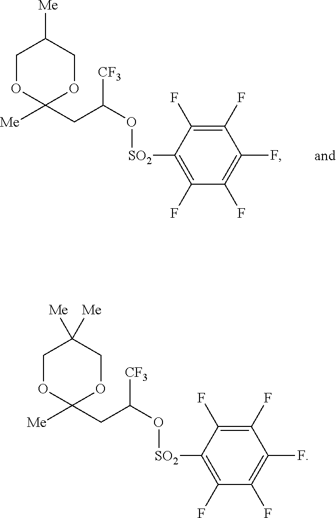

In certain embodiments, the invention relates to a compound of formula

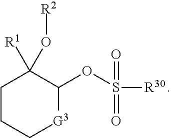

In these embodiments, R^{g} is represented by R¹ and —OR². In some of these embodiments, R¹ is chosen from (C₁-C₆)alkyl and benzyl. In some of these embodiments, R² is chosen from H and R^{h}CH₂CO—.

In some embodiments, the invention relates to a compound of formula

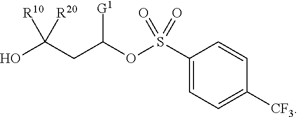

In these embodiments, R¹⁰ is (C₁-C₈)saturated hydrocarbon. In some of these embodiments, R²⁰ is chosen from H and (C₁-C₆) hydrocarbon. In some of these embodiments, G¹ is selected from —N⁺(CH₃)₃, —(CH₂)—N⁺(CH₃)₃, —(CH₂)—NO₂, —CH₂(CN), —CH(CN)₂, —C₆F₅, —(CH₂)₀₋₁SO₂(C₁-C₈)hydrocarbon, —Si(CH₃)₃, halogen, —CᵢHⱼ(halogen)ₖ, and CₛHₜ(halogen)ᵤ-E, wherein i is 1-2, j is 0-3, k is 1-5, and the sum of j plus k is 2i+1; and wherein s is 1-2, t is 0-2, u is 1-4, and the sum of t plus u is 2s. In some of these embodiments, E is selected from —(C₁-C₆)alkyl, aryl, (C₁-C₆)haloalkyl, haloaryl, haloaryl(C₁-C₂)alkyl, and aryl(C₁-C₂)alkyl. In some of these embodiments, both R¹⁰ and R²⁰ are methyl.

In certain embodiments, the invention relates to compounds selected from the group below:

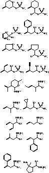

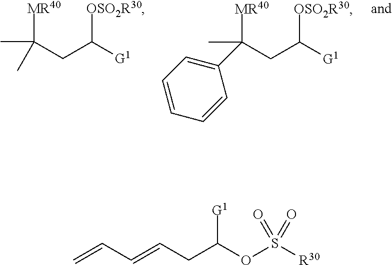

wherein R³⁵ is selected from hydrogen, (C₁-C₆)alkyl and benzyl.

In the context of the present application, alkyl is intended to include linear, branched, or cyclic saturated hydrocarbon structures and combinations thereof. Lower alkyl refers to alkyl groups of from 1 to 6 carbon atoms. Examples of lower alkyl groups include methyl, ethyl, propyl, isopropyl, butyl, s-and t-butyl and the like. Preferred alkyl groups are those of C₂₀ or below. Cycloalkyl is a subset of alkyl and includes cyclic hydrocarbon groups of from 3 to 8 carbon atoms. Examples of cycloalkyl groups include c-propyl, c-butyl, c-pentyl, norbornyl and the like.

Silaalkane (or silaalkyl) refers to alkyl residues in which one or more carbons have been replaced by silicon. Examples include trimethylsilylmethyl [(CH₃)₃SiCH₂—] and trimethylsilane [(CH₃)₃Si—].

C₁ to C₂₀ hydrocarbon includes alkyl, cycloalkyl, polycycloalkyl, alkenyl, alkynyl, aryl and combinations thereof. Examples include benzyl, phenethyl, cyclohexylmethyl, camphoryl and naphthylethyl. The term “carbocycle” is intended to include ring systems consisting entirely of carbon but of any oxidation state. Thus (C₃-C₁₀) carbocycle refers to such systems as cyclopropane, benzene and cyclohexene; (C₈-C₁₂) carbopolycycle refers to such systems as norbornane, decalin, indane and naphthalene.

Alkoxy or alkoxyl refers to groups of from 1 to 8 carbon atoms of a straight, branched, cyclic configuration and combinations thereof attached to the parent structure through an oxygen. Examples include methoxy, ethoxy, propoxy, isopropoxy, cyclopropyloxy, cyclohexyloxy and the like. Lower-alkoxy refers to groups containing one to four carbons.

Oxaalkyl refers to alkyl residues in which one or more carbons (and their associated hydrogens) have been replaced by oxygen. Examples include methoxy, methoxypropoxy, 3,6,9-trioxadecyl and the like. The term oxaalkyl is intended as it is understood in the art [see Naming and Indexing of Chemical Substances for Chemical Abstracts, published by the American Chemical Society, ¶196, but without the restriction of ¶127(a)], i.e. it refers to compounds in which the oxygen is bonded via a single bond to its adjacent atoms (forming ether bonds); it does not refer to doubly bonded oxygen, as would be found in carbonyl groups. Similarly, thiaalkyl and azaalkyl refer to alkyl residues in which one or more carbons has been replaced by sulfur or nitrogen, respectively. Examples include ethylaminoethyl and methylthiopropyl.

Acyl refers to groups of from 1 to 8 carbon atoms of a straight, branched, cyclic configuration, saturated, unsaturated and aromatic and combinations thereof, attached to the parent structure through a carbonyl functionality. Acyl also refers to formyl, which has only a hydrogen attached to the parent structure through a carbonyl functionality. One or more carbons in the acyl residue may be replaced by nitrogen, oxygen or sulfur as long as the point of attachment to the parent remains at the carbonyl. Examples include acetyl, benzoyl, propionyl, isobutyryl, t-butoxycarbonyl, benzyloxycarbonyl and the like. Lower-acyl refers to groups containing one to four carbons.

Aryl and heteroaryl mean a 5- or 6-membered aromatic or heteroaromatic ring containing 0-3 heteroatoms selected from O, N, or S; a bicyclic 9- or 10-membered aromatic or heteroaromatic ring system containing 0-3 heteroatoms selected from O, N, or S; or a tricyclic 13- or 14-membered aromatic or heteroaromatic ring system containing 0-3 heteroatoms selected from O, N, or S. The aromatic 6- to 14-membered carbocyclic rings include, e.g., benzene, naphthalene, indane, tetralin, and fluorene and the 5- to 10-membered aromatic heterocyclic rings include, e.g., imidazole, pyridine, indole, thiophene, benzopyranone, thiazole, furan, benzimidazole, quinoline, isoquinoline, quinoxaline, pyrimidine, pyrazine, tetrazole and pyrazole.

Arylalkyl refers to a substituent in which an aryl residue is attached to the parent structure through alkyl. Examples are benzyl, phenethyl and the like. Heteroarylalkyl refers to a substituent in which a heteroaryl residue is attached to the parent structure through alkyl. Examples include, e.g., pyridinylmethyl, pyrimidinylethyl and the like.

Heterocycle means a cycloalkyl or aryl residue in which from one to three carbons is replaced by a heteroatom selected from the group consisting of N, O and S. The nitrogen and sulfur heteroatoms may optionally be oxidized, and the nitrogen heteroatom may optionally be quaternized. Examples of heterocycles that fall within the scope of the invention include pyrrolidine, pyrazole, pyrrole, indole, quinoline, isoquinoline, tetrahydroisoquinoline, benzofuran, benzodioxan, benzodioxole (commonly referred to as methylenedioxyphenyl, when occurring as a substituent), tetrazole, morpholine, thiazole, pyridine, pyridazine, pyrimidine, thiophene, furan, oxazole, oxazoline, isoxazole, dioxane, tetrahydrofuran and the like. It is to be noted that heteroaryl is a subset of heterocycle in which the heterocycle is aromatic. Examples of heterocyclyl residues additionally include piperazinyl, 2-oxopiperazinyl, 2-oxopiperidinyl, 2-oxo-pyrrolidinyl, 2-oxoazepinyl, azepinyl, 4-piperidinyl, pyrazolidinyl, imidazolyl, imidazolinyl, imidazolidinyl, pyrazinyl, oxazolidinyl, isoxazolidinyl, thiazolidinyl, isothiazolyl, quinuclidinyl, isothiazolidinyl, benzimidazolyl, thiadiazolyl, benzopyranyl, benzothiazolyl, tetrahydrofuryl, tetrahydropyranyl, thienyl, benzothienyl, thiamorpholinyl, thiamorpholinylsulfoxide, thiamorpho-linylsulfone, oxadiazolyl, triazolyl and tetrahydroquinolinyl. An oxygen heterocycle is a heterocycle containing at least one oxygen in the ring; it may contain additional oxygens, as well as other heteroatoms. A sulphur heterocycle is a heterocycle containing at least one sulphur in the ring; it may contain additional sulphurs, as well as other heteroatoms. Oxygen heteroaryl is a subset of oxygen heterocycle; examples include furan and oxazole. Sulphur heteroaryl is a subset of sulphur heterocycle; examples include thiophene and thiazine. A nitrogen heterocycle is a heterocycle containing at least one nitrogen in the ring; it may contain additional nitrogens, as well as other heteroatoms. Examples include piperidine, piperazine, morpholine, pyrrolidine and thiomorpholine. Nitrogen heteroaryl is a subset of nitrogen heterocycle; examples include pyridine, pyrrole and thiazole.

As used herein, the term “optionally substituted” may be used interchangeably with “unsubstituted or substituted”. The term “substituted” refers to the replacement of one or more hydrogen atoms in a specified group with a specified radical. For example, substituted alkyl, aryl, cycloalkyl, heterocyclyl etc. refer to alkyl, aryl, cycloalkyl, or heterocyclyl wherein one or more H atoms in each residue are replaced with halogen, haloalkyl, alkyl, acyl, alkoxyalkyl, hydroxyloweralkyl, carbonyl, phenyl, heteroaryl, benzenesulfonyl, hydroxy, loweralkoxy, haloalkoxy, oxaalkyl, carboxy, alkoxycarbonyl [—C(═O)O-alkyl], cyano, acetoxy, nitro, mercapto, alkylthio, alkylsulfinyl, alkylsulfonyl, aryl, benzyl, oxaalkyl, and benzyloxy. “Oxo” is also included among the substituents referred to in “optionally substituted”; it will be appreciated by persons of skill in the art that, because oxo is a divalent radical, there are circumstances in which it will not be appropriate as a substituent (e.g. on phenyl). In one embodiment, 1, 2 or 3 hydrogen atoms are replaced with a specified radical. In the case of alkyl, cycloalkyl and aryl, more than three hydrogen atoms can be replaced by fluorine; indeed, all available hydrogen atoms could be replaced by fluorine.

The term “halogen” means fluorine, chlorine, bromine or iodine.

Some of the compounds described herein contain one or more asymmetric centers and may thus give rise to enantiomers, diastereomers, and other stereoisomeric forms that may be defined, in terms of absolute stereochemistry, as (R)- or (S)-. Unless indicated otherwise, the present invention is meant to include all such possible isomers, as well as, their racemic and optically pure forms. Optically active (R)- and (S)-, or (D)- and (L)-isomers may be prepared using chiral synthons or chiral reagents, or resolved using conventional techniques. When the compounds described herein contain olefinic double bonds or other centers of geometric asymmetry, and unless specified otherwise, it is intended that the compounds include both E and Z geometric isomers. Likewise, all tautomeric forms are also intended to be included.

The configuration of any carbon-carbon double bond other than an endocyclic double bond appearing herein is selected for convenience only and is not intended to designate a particular configuration; thus a carbon-carbon double bond depicted arbitrarily herein as trans may be cis, trans, or a mixture of the two in any proportion.

Terminology related to “protecting”, “deprotecting” and “protected” functionalities occurs in some places in this application. Such terminology is well understood by persons of skill in the art and is used in the context of processes which involve sequential treatment with a series of reagents. In that context, a protecting group refers to a group which is used to mask a functionality during a process step in which it would otherwise react, but in which reaction is undesirable. The protecting group prevents reaction at that step, but may be subsequently removed to expose the original functionality. The removal or “deprotection” occurs after the completion of the reaction or reactions in which the functionality would interfere. Thus, when a sequence of reagents is specified, as it is in the processes of the invention, the person of ordinary skill can readily envision those groups that would be suitable as “protecting groups”.

The following abbreviations and terms have the indicated meanings throughout:

Ac=acetyl
BNB=4-bromomethyl-3-nitrobenzoic acid
Boc=t-butyloxy carbonyl
Bu=butyl
c-=cyclo
DBU=diazabicyclo[5.4.0]undec-7-ene
DCM=dichloromethane=methylene chloride=CH₂Cl₂
DEAD=diethyl azodicarboxylate
DIC=diisopropylcarbodiimide
DIEA=N,N-diisopropylethyl amine

### DMAP=4-N,N-dimethylaminopyridine

### DMF=N,N-dimethylformamide

DMSO=dimethyl sulfoxide
DVB=1,4-divinylbenzene
EEDQ=2-ethoxy-1-ethoxycarbonyl-1,2-dihydroquinoline

### ESCAP=Environmentaly Stable Chemically Amplified Photoresist

Et=ethyl
Fmoc=9-fluorenylmethoxycarbonyl
GC=gas chromatography
HATU=O-(7-Azabenzotriazol-1-yl)-1,1,3,3-tetramethyluronium hexafluorophosphate
HOAc=acetic acid
HOBt=hydroxybenzotriazole
Me=methyl
mesyl=methanesulfonyl
Ms=mesyl
MTBE=methyl t-butyl ether
NMO=N-methylmorpholine oxide
-OTf=triflate=trifluoromethanesulfonate=—OSO₂CF₃
PEB=post-exposure bake
PEG=polyethylene glycol
Ph or κ=phenyl
PhOH=phenol
PfP=pentafluorophenol
PPTS=pyridinium p-toluenesulfonate
PyBroP=bromo-tris-pyrrolidino-phosphonium hexafluorophosphate
rt=room temperature
sat'd=saturated
s-=secondary
t-=tertiary
TBDMS=t-butyldimethylsilyl
-Tf=trifyl=trifluoromethyl sulfonyl=—SO₂CF₃
triflate=-OTf=—OSO₂CF₃
TFA=trifluoroacetic acid
T_{g}=glass transition temperature
THF=tetrahydrofuran
TMOF=trimethyl orthoformate
TMS=trimethylsilyl
tosyl=Ts=p-toluenesulfonyl=—SO₂-para-(C₆H₄)—CH₃
tosylate=-OTs=—OSO₂-para-(C₆H₄)—CH₃
Trt=triphenylmethyl

A comprehensive list of abbreviations utilized by organic chemists (i.e. persons of ordinary skill in the art) appears in the first issue of each volume of the Journal of Organic Chemistry. The list, which is typically presented in a table entitled “Standard List of Abbreviations” is incorporated herein by reference.

References herein to acid strengths or, equivalently, pKₐ values, particularly with respect to sulfonic and/or photolytically generated acids, refer to values determined by Taft parameter analysis, as such analysis is known in the art and described for example in J. Cameron et al., “Structural Effects of Photoacid Generators on Deep UV Resist Performance,” Society of Plastic Engineers, Inc. Proceedings., “Photopolymers, Principles, Processes and Mateials”, 11th International Conference, pp. 120-139 (1997) and J. P. Gutthrie, Can. J. Chem., 56:2342-2354 (1978). As reported in U.S. Pat. No. 6,803,169, HOTs (paratoluene sulfonic acid) has a pKₐ of −2.66 as determined by Taft parameter analysis. Thus, an acid which is at least as strong as HOTs will have a pKₐ of −2.66 or lower, as determined by Taft parameter analysis.

As used herein, the term “sulfonic acid precursor” refers to a molecule which can be decomposed in acidic conditions to generate HOSO₂R³.

As used herein, the term “photoresist polymer” refers to a polymer which may serve as the primary component in a photoresist.

As used herein, the term “photoresist substrate” refers to an article, such as a silicon wafer, which is suitable for use as a substrate in photolithography or other similar processes, and thus may have a photoresist applied thereto as part of the photolithography process.

As used herein, the term “photoresist composition” refers to a composition which may be used in connection with photolithography.

As is known in the art, ESCAP (Environmentaly Stable Chemically Amplified Photoresist) polymers undergo well-known acid catalysis reactions. A central feature of these chemical systems is that the acidolysis reactions only occur in the presence of acid, i.e. catalytically, and they do not occur thermally without acid, except at temperatures ˜50° C. above normal post-exposure bake temperatures used in integrated circuit fabrication, i.e at temperatures of approximately 65-140° C. Other types of chemically amplified resists (often called low activation energy resists) can use lower post-exposure temperatures of approximately 20-120° C.

The sulfonic acid precursors provided or utilized in accordance with embodiments of the present invention can be thought of as acid amplifiers which have two parts, a “trigger” and a sulfonate group. The “trigger” is a leaving group which is bonded to the remainder of the molecule such that the bond is thermolytically stable at temperatures at which the substrates are processed, but in the presence of acid becomes sufficiently labile to enable elimination of the protonated leaving group and a proton, resulting in a carbon-carbon double bond. Two generic but non-limitative illustrations are provided in Scheme 1. As is illustrated in Scheme 1, in some embodiments of the invention, the leaving group is at the carbon labeled gamma and the sulfonate is at the carbon labeled alpha, i.e. there is hydrogen-bearing carbon atom between the carbon atoms to which the leaving group and sulfonate group are respectively attached.

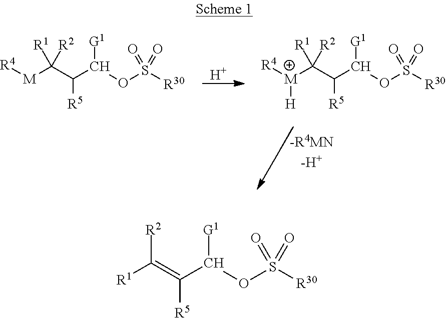

As shown illustratively in Scheme 1, as a result of elimination of the leaving group, the sulfonate becomes an allylic sulfonate, which, relative to the alkyl sulfonate that existed prior to elimination of the leaving group, is activated toward dissociation. Dissociation of the sulfonate moiety and loss of a proton results in a conjugated pi-system. This is non-limitatively illustrated in Scheme 2, in which R¹*, R²* and R⁵* denote R¹, R² and R⁵, respectively, which have lost a proton.

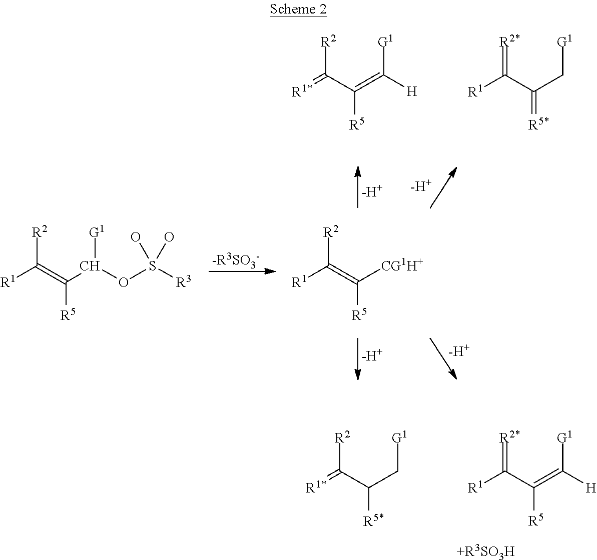

It will be appreciated that because the generation of the sulfonic acid by the sulfonic acid precursor is driven, in part, by the formation of a conjugated pi-system, molecules which will not enable the formation of such systems, e.g. molecules in which the sulfonate is adjacent to a bridgehead carbon such as 2- or 7-sulfonyl norbornane, are beyond the scope of embodiments of the present invention.

Photoresist polymers, i.e polymers suitable for use with photoacid generators and/or acid amplifiers in making photoresists are well-known in the art. See, e.g. U.S. Pat. No. 6,617,086, U.S. Pat. No. 6,803,169, US 2003/0134227 and US 2005/0147916, the contents of all of which are incorporated herein by reference. For example, by way of illustration, U.S. Pat. No. 6,803,169 describes various polymers, referred to therein as “deblocking resins”, suitable for use in forming photoresists, in particular positive photoresists. Such polymers are referred to therein as containing “acid labile groups”, i.e. moieties which can easily be removed by acid, “such as acid sensitive esters, carbonates, acetals, ketals and the like, which suitably may be pendant from a polymer backbone. Acid-labile groups that are integral to the polymer backbone also may be employed”. Portions of the polymer in which acid labile groups have been removed by contact with photolytically generated acid will be susceptible to dissolution by base during the development of the photoresist. As explained therein, the deblocking resins may be deblocking resins as described in European Patent Published Application EP0813113A1 (corresponding to U.S. Pat. No. 5,861,231), European Patent Application 97115532 (corresponding to U.S. Pat. No. 5,861,231), U.S. Pat. No. 5,258,257, U.S. Pat. Nos. 4,968,581, 4,883,740, 4,810,613, 4,491,628 and 5,492,793. U.S. Pat. No. 6,803,169 goes on to state that:

“Preferred deblocking resins for use in the resists of the invention include polymers that contain both phenolic and non-phenolic units. For example, one preferred group of such polymers has acid labile groups substantially, essentially or completely only on non-phenolic units of the polymer. One preferred polymer binder has repeating units x and y of the following formula:

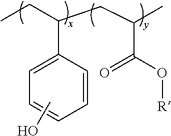

wherein the hydroxyl group be present at either the ortho, meta or para positions throughout the polymer, and R′ is substituted or unsubstituted alkyl having 1 to about 18 carbon atoms, more typically 1 to about 6 to 8 carbon atoms. Tert-butyl is a generally employed R′ group. An R′ group may be optionally substituted by e.g. one or more halogen (particularly F, Cl or Br), C₁₋₈ alkoxy, C₂₋₈ alkenyl, etc. The depicted phenolic units of the polymer also may be optionally substituted by such groups. The units x and y may be regularly alternating in the polymer, or may be randomly interspersed through the polymer. Such copolymers can be readily formed. For example, for resins of the above formula, vinyl phenols and a substituted or unsubstituted alkyl acrylate such as t-butylacrylate and the like may be condensed under free radical conditions as known in the art. The substituted ester moiety, i.e. R′—O—C(═O)—, of the acrylate units serves as the acid labile groups of the resin and will undergo photoacid induced cleavage upon exposure of a coating layer of a photoresist containing the resin. The copolymer may have a Mw of from about 3,000 to about 50,000, for example about 10,000 to about 30,000 with a molecular weight distribution of about 3 or less; in some embodiments, a molecular weight distribution of about 2 or less. Such copolymers also may be prepared by such free radical polymerization or other known procedures and suitably will have a Mw of from about 3,000 to about 50,000, and a molecular weight distribution of about 3 or less, and in some embodiments about 2 or less.

“Additional preferred deblocking resins have acid labile groups on both phenolic and non-phenolic units of the polymer. One exemplary polymer binder has repeating units a, b and c of the following formula:

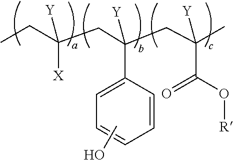

wherein R′ group is a photoacid labile group as defined above for the other exemplary polymer; X is another repeat unit which may or may not contain a photoacid labile group; and each Y is independently hydrogen or C₁₋₆ alkyl, preferably hydrogen or methyl. The values a, b and c designate the molar amount of the polymer units. Those polymer units may be regularly alternating in the polymer, or may be randomly interspersed through the polymer. Suitable X groups may be aliphatic or aromatic groups such as phenyl, cyclohexyl, adamantyl, isobornylacrylate, methacrylate, isobornylmethacrylate, and the like. Such polymers may be formed in the same manner as described for the polymer above, and wherein the formed copolymer is reacted to provide the phenolic acid labile groups.

“Additional deblocking resins include at least three distinct repeating units of 1) units that contain acid-labile groups; 2) units that are free of reactive groups as well as hydroxy groups; and 3) aromatic or other units that contribute to aqueous developability of a photoresist containing the polymer as a resin binder. Particular examples of deblocking polymers of this type correspond to” the following formula:

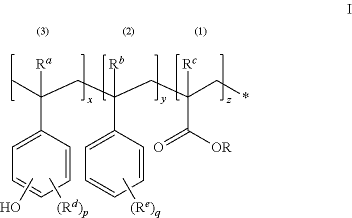

wherein R of units (1) is substituted or unsubstituted alkyl preferably having 1 to about 10 carbon atoms, more typically 1 to about 6 carbons. Branched alkyls, such as tert-butyl, are exemplary R groups. Also, the polymer may comprise a mixture of different R groups, e.g., by using a variety of acrylate monomers during the polymer synthesis.

R^{b} groups of units (2) of the above formula each independently may be e.g. halogen (particularly F, Cl and Br), substituted or unsubstituted alkyl preferably having 1 to about 8 carbons, substituted or unsubstituted alkoxy preferably having 1 to about 8 carbon atoms, substituted or unsubstituted alkenyl preferably having 2 to about 8 carbon atoms, substituted or unsubstituted alkynyl preferably having 2 to about 8 carbons, substituted or unsubstituted alkylthio preferably having 1 to about 8 carbons, cyano, nitro, etc.; and q is an integer of from 0 (where the phenyl ring is fully hydrogen-substituted) to 5, for example 0, 1 or 2. Also, two R^{b} groups on adjacent carbons may be taken together to form (with ring carbons to which they are attached) one, two or more fused aromatic or alicyclic rings having from 4 to about 8 ring members per ring. For example, two R^{b} groups can be taken together to form (together with the depicted phenyl) a naphthyl or acenaphthyl ring. As with units (1), the polymer may comprise a mixture of different units (2) with differing R^{b} groups or no R^{b} groups (i.e. q=0) by using a variety of substituted or unsubstituted vinylphenyl monomers during the polymer synthesis.

R^{a} groups of units (3) of the above Formula I each independently may be e.g. halogen (particularly F, Cl and Br), substituted or unsubstituted alkyl preferably having 1 to about 8 carbons, substituted or unsubstituted alkoxy preferably having 1 to about 8 carbon atoms, substituted or unsubstituted alkenyl preferably having 2 to about 8 carbon atoms, substituted or unsubstituted sulfonyl preferably having 1 to about to about 8 carbon atoms such as mesyl (CH₃SO₂O—), substituted or unsubstituted alkyl esters such as those represented by RCOO— where R is preferably an alkyl group preferably having 1 to about 10 carbon atoms, substituted or unsubstituted alkynyl preferably having 2 to about 8 carbons, substituted or unsubstituted alkylthio preferably having 1 to about 8 carbons, cyano, nitro, etc.; and p is an integer of from 0 (where the phenyl ring has a single hydroxy substituent) to 4, for example 0, 1 or 2. Also, two R^{a} groups on adjacent carbons may be taken together to form (with ring carbons to which they are attached) one, two or more fused aromatic or alicyclic rings having from 4 to about 8 ring members per ring. For example, two R^{a} groups can be taken together to form (together with the phenol depicted in Formula I) a naphthyl or acenaphthyl ring. As with units (1), the polymer may comprise a mixture of different units (3) with differing R^{a} groups or no R^{a} groups (i.e. p=0) by using a variety of substituted or unsubstituted vinylphenyl monomers during the polymer synthesis. As shown in Formula I above, the hydroxyl group of units (3) may be either at the ortho, meta or para positions throughout the copolymer. Para or meta substitution is generally preferred.

Each R^{a}, R^{b} and R^{c} substituent independently may be hydrogen or substituted or unsubstituted alkyl preferably having 1 to about 8 carbon atoms, more typically 1 to about 6 carbons, or more preferably 1 to about 3 carbons.

The above-mentioned substituted groups (i.e. substituted groups R and R^{a} through R^{e} of Formula I above) may be substituted at one or more available positions by one or more suitable groups such as halogen (particularly F, Cl or Br); C₁₋₈ alkyl; C₁₋₈ alkoxy; C₂₋₈ alkenyl; C₂₋₈ alkynyl; aryl such as phenyl; alkanoyl such as a C₁₋₆ alkanoyl of acyl and the like; etc. Typically a substituted moiety is substituted at one, two or three available positions.

In the above Formula I, x, y and z are the mole fractions or percents of units (3), (2) and (1) respectively in the copolymer. These mole fractions may suitably vary over rather wide values, e.g., x may be suitably from about 10 to 90 percent, more preferably about 20 to 90 percent; y may be suitably from about 1 to 75 percent, more preferably about 2 to 60 percent; and z may be 1 to 75 percent, more preferably about 2 to 60 percent.

Preferred copolymers of the above Formula I include those where the only polymer units correspond to the general structures of units (1), (2) and (3) above and the sum of the mole percents x, y and z equals one hundred. However, preferred polymers also may comprise additional units wherein the sum of x, y and z would be less than one hundred, although preferably those units (1), (2) and (3) would still constitute a major portion of the copolymer, e.g. where the sum of x, y and z would be at least about 50 percent (i.e. at least 50 molar percent of the polymer consists of units (1), (2) and (3)), more preferably the sum of x, y and z is at least 70 percent, and still more preferably the sum of x, y and z is at least 80 or 90 percent. See European Published Patent Application EP 0813113A1 [corresponding to U.S. Pat. No. 5,861,231] for detailed disclosure of free radical synthesis of copolymers of the above Formula I.

Additional resin binders include those that have acetalester and/or ketalester deblocking groups. Such resins are disclosed in EP 0829766A2 of the Shipley Company [corresponding to U.S. Pat. No. 6,090,526] and U. Kumar. For instance, suitable resins include terpolymers formed from hydroxystryene, styrene and acid labile components such as 1-propyloxy-1-ethylmethacrylate and the like.

Additional preferred polymers are disclosed in U.S. Pat. No. 6,136,501.

U.S. Pat. No. 6,803,169 states that “Polymers of the invention can be prepared by a variety of methods. One suitable method is free radical polymerization, e.g., by reaction of selected monomers to provide the various units as discussed above in the presence of a radical initiator under an inert atmosphere (e.g., N₂ or argon) and at elevated temperatures such as about 70° C. or greater, although reaction temperatures may vary depending on the reactivity of the particular reagents employed and the boiling point of the reaction solvent (if a solvent is employed). Suitable reaction solvents include e.g. tetrahydrofuran, dimethylformamide and the like. Suitable reaction temperatures for any particular system can be readily determined empirically by those skilled in the art based on the present disclosure. Monomers that can be reacted to provide a polymer of the invention can be readily identified by those skilled in the art based on the present disclosure. For example, suitable monomers include e.g. acrylate, including methacrylate, t-butylacrylate, acrylonitrile, methacrylonitrile, itaconic anhydride and the like. A variety of free radical initiators may be employed to prepare the copolymers of the invention. For example, azo compounds may be employed such as azo-bis-2,4-dimethylpentanenitrile. Peroxides, peresters, peracids and persulfates also could be employed.

“Unless indicated otherwise above, a polymer used as a resin binder component of a resist of the invention typically will have a weight average molecular weight (M_{w}) of 1,000 to about 100,000, more preferably about 2,000 to about 30,000, still more preferably from about 2,000 to 15,000 or 20,000, with a molecular weight distribution (M_{w}/Mₙ) of about 3 or less, more preferably a molecular weight distribution of about 2 or less. Molecular weights (either M_{w} or Mₙ) of the polymers of the invention are suitably determined by gel permeation chromatography.

“Preferred polymers also will exhibit a sufficiently high T_{g} to facilitate use of the polymer in a photoresist. Thus, preferably a polymer will have a T_{g} greater than typical softbake (solvent removal) temperatures, e.g. a T_{g} of greater than about 100° C., more preferably a T_{g} of greater than about 110° C., still more preferably a T_{g} of greater than about 120° C.

“For 193 nm imaging applications, preferably a resist resin binder component will be substantially free of any phenyl or other aromatic groups. For example, preferred polymers for use in 193 imaging contain less than about 1 mole percent aromatic groups, more preferably less than about 0.1, 0.02, 0.04 and 0.08 mole percent aromatic groups and still more preferably less than about 0.01 mole percent aromatic groups. Particularly preferred polymers are completely free of aromatic groups. Aromatic groups can be highly absorbing of sub-200 nm radiation and thus are undesirable for polymers used in photoresists imaged 193 nm.”

Photoresists also may contain other materials. For example, other optional additives include actinic and contrast dyes, anti-striation agents, plasticizers, speed enhancers, etc. Such optional additives typically will be present in minor concentration in a photoresist composition except for fillers and dyes which may be present in relatively large concentrations such as, e.g., in amounts of from 5 to 30 percent by weight of the total weight of a resist's dry components. A common additive is a basic compound, such as tetrabutylammonium hydroxide (TBAH), tetrabutylammonium lactate, or tetrabutylammonium acetate, which can enhance resolution of a developed image. For resists imaged at 193 nm, an exemplary base is a hindered amine such as diazabicycloundecene, diazabicyclononene or diterbutylethanolamine. Such an amine may be suitably present in amount of about 0.03 to 5 to 10 weight percent, based on total solids (all components except solvent) of a resist composition.

The PAG blend component should be present in a photoresist formulation in amount sufficient to enable generation of a latent image in a coating layer of the resist. More specifically, the PAG blend will suitably be present in an amount of from about 0.5 to 40 weight percent of total solids of a resist, more typically from about 0.5 to 10 weight percent of total solids of a resist composition. The distinct PAGs of a blend suitably may be present in about equivalent molar amounts in a resist composition, or each PAG may be present in differing molar amounts. It is typically preferred however that each class or type of PAG is present in an amount of at least about 20 to 25 mole percent of total PAG present in a resist formulation.

The resin binder component of resists are typically used in an amount sufficient to render an exposed coating layer of the resist developable such as with an aqueous alkaline solution. More particularly, a resin binder will suitably comprise 50 to about 90 weight percent of total solids of the resist.

Photoresists are generally prepared following known procedures. For example, a resist can be prepared as a coating composition by dissolving the components of the photoresist in a suitable solvent such as, e.g., a glycol ether such as 2-methoxyethyl ether (diglyme), ethylene glycol monomethyl ether, propylene glycol monomethyl ether, propylene glycol monomethyl ether acetate; lactates such as ethyl lactate or methyl lactate, with ethyl lactate being preferred; proponiates, particularly methyl propionate, ethyl propionate and ethyl ethoxy propionate; a Cellosolve ester such as methyl Cellosolve acetate; an aromatic hydrocarbon such toluene or xylene; a ketone such as methylethyl ketone or cyclohexanone; and the like. Typically the solids content of the photoresist varies between 5 and 35 percent by weight of the total weight of the photoresist composition.

The photoresists can be used in accordance with known procedures. Though photoresists may be applied as a dry film, they are preferably applied on a substrate as a liquid coating composition, dried by heating to remove solvent preferably until the coating layer is tack free, exposed through a photomask to activating radiation, optionally post-exposure baked to create or enhance solubility differences between exposed and nonexposed regions of the resist coating layer, and then developed preferably with an aqueous alkaline developer to form a relief image.

The substrate suitably can be any substrate used in processes involving photoresists such as a microelectronic wafer. For example, the substrate can be a silicon, silicon dioxide or aluminum-aluminum oxide microelectronic wafer. Gallium arsenide, ceramic, quartz or copper substrates may also be employed. Substrates used for liquid crystal display and other flat panel display applications are also employed, e.g. glass substrates, indium tin oxide coated substrates and the like. As discussed above, it has been found that highly resolved resist relief images can be formed on substrates that can be difficult to pattern fine images, such as boron phosphorus silicate glass. A liquid coating resist composition may be applied by any standard means such as spinning, dipping or roller coating.

Rather than applying a resist composition directly onto a substrate surface, a coating layer of an antireflective coating composition may be first applied onto a substrate surface and the photoresist coating layer applied over the underlying antireflective coating. A number of antireflective coating compositions may be employed including the compositions disclosed in European Applications Publication Nos. 0542008A1 and 0813114A2, both of the Shipley Company. For resists to be imaged at 248 nm, an antireflective composition that contains a resin binder with anthracene units preferably may be employed.

The exposure energy should be sufficient to effectively activate the photoactive component of the radiation sensitive system to produce a patterned image in the resist coating layer. Suitable exposure energies typically range from about 10 to 300 mJ/cm². An exposure wavelength in the deep U.V. range often will be used for the photoresists as disclosed herein, particularly exposure wavelengths of sub-250 nm or sub-200 nm such as about 248 nm or 193 nm. The exposed resist coating layer can be thermally treated after exposure and prior to development, with suitable post-exposure bake temperatures being from about e.g. 50° C. or greater, more specifically from about 50 to 160° C. After development, the substrate surface bared by development may then be selectively processed, for example chemically etching or plating substrate areas bared of photoresist in accordance with procedures known in the art. Suitable etchants include a hydrofluoric acid etching solution and a plasma gas etch such as an oxygen plasma etch.

Thus, in embodiments of the present invention, photoresist polymers known in the art, such as those described in U.S. Pat. No. 6,803,169 or in the references cited therein and which are mentioned in the quoted text above may be used. Resists per se in accordance with embodiments of the present invention may be likewise be prepared in accordance with methods known in the art, for example as described in U.S. Pat. No. 6,803,169, e.g. by dissolving the components of the photoresist in a suitable solvent such as, e.g., a glycol ether such as 2-methoxyethyl ether (diglyme), ethylene glycol monomethyl ether, propylene glycol monomethyl ether, propylene glycol monomethyl ether acetate; lactates such as ethyl lactate or methyl lactate; proponiates, particularly methyl propionate, ethyl propionate and ethyl ethoxy propionate; a Cellosolve ester such as methyl Cellosolve acetate; an aromatic hydrocarbon such toluene or xylene; a ketone such as methylethyl ketone or cyclohexanone; and the like; and applying the solution to a substrate and baking. Typically the solids content of the photoresist varies between 5 and 35 percent by weight of the total weight of the photoresist composition.

In some embodiments, the sulfonic acid precursor may be included in the photoresist composition as a molecule separate from the polymer. In other embodiments, the sulfonic acid precursor may be incorporated into the polymer chain. For example, if the photoresist polymer is a terpolymer having the structure

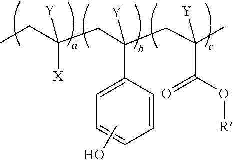

as defined in U.S. Pat. No. 6,803,169, R′ may be the sulfonic acid precursor. This can be accomplished, for example, by including in the mix of monomers used to produce the polymer an amount of a compound of formula:

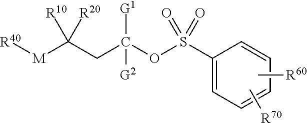

wherein R⁶⁰ is chosen from —CH₂Br, —CH═CH₂, and —OCH₂CH₂Br, thus allowing the compound to be incorporated into a polymer backbone. If another acrylic acid-derived monomer containing a different group R′, e.g. tert-butyl, is also employed in the polymer synthesis, this will result in a quadpolymer rather than the terpolymer shown. Alternatively, a small amount of the quadpolymer (or terpolymer) incorporating the sulfonic acid generating compound (only) may be synthesized, and in preparing the photoresist this quad- or terpolymer may be blended with a larger amount of a terpolymer in which R′ is not a sulfonic acid generating group.

The amount of sulfonic acid precursor employed may be up to 40 mol. % of the solids of the photoresist composition, for example, between 1 and 30 mol. % of the solids of the photoresist composition, for example 2 to 20 mol. %. In the case where the sulfonic acid precursor is incorporated into the polymer, the monomer may constitute up to 40 mol. % of the polymer, for example 1 to 30% mol. % or 2 to 20% mol. %.

In some embodiments of the present invention, the photoresist composition includes a photoacid generator (PAG). PAGs are well-known in the art, see for example EP 0164248, EP 0232972, EP 717319A1, U.S. Pat. No. 4,442,197, U.S. Pat. No. 4,603,101, U.S. Pat. No. 4,624,912, U.S. Pat. No. 5,558,976, U.S. Pat. No. 5,879,856, U.S. Pat. No. 6,300,035, U.S. Pat. No. 6,803,169 and US 2003/0134227, the contents of all of which are incorporated herein by reference, and include, for example, di-(t-butylphenyl)iodonium triflate, di-(t-butylphenyl)iodonium perfluorobutanesulfonate, di-(4-tert-butylphenyl)iodonium perfluoroctanesulfonate, di-(4-t-butylphenyl)iodonium o-trifluoromethylbenzenesulfonate, di-(4-t-butylphenyl)iodonium camphorsulfonate, di-(t-butylphenyl)iodonium perfluorobenzenesulfonate, di-(t-butylphenyl)iodonium p-toluenesulfonate, triphenyl sulfonium triflate, triphenyl sulfonium perfluorobutanesulfonate, triphenyl sulfonium perfluoroctanesulfonate, triphenyl sulfonium o-trifluoromethylbenzenesulfonate, triphenyl sulfonium camphorsulfonate, triphenyl sulfonium perfluorobenzenesulfonate, triphenyl sulfonium p-toluenesulfonate, N-[(trifluoromethane sulfonyl)oxy]-5-norbornene-2,3-dicarboximide, N-[(perfluorobutane sulfonyl)oxy]-5-norbornene-2,3-dicarboximide, N-[(perfluorooctane sulfonyl)oxy]-5-norbornene-2,3-dicarboximide, N-[(o-trifluoromethylbenzene sulfonyl)oxy]-5-norbornene-2,3-dicarboximide, N-[(camphor sulfonyl)oxy]-5-norbornene-2,3-dicarboximide, N-[(perfluorobenzene sulfonyl)oxy]-5-norbornene-2,3-dicarboximide, N-[(p-toluenesulfonate sulfonyl)oxy]-5-norbornene-2,3-dicarboximide, phthalimide triflate, phthalimide perfluorobutanesulfonate, phthalimide perfluoroctanesulfonate, phthalimide o-trifluoromethylbenzenesulfonate, phthalimide camphorsulfonate, phthalimide perfluorobenzenesulfonate, phthalimide p-toluenesulfonate, diphenyl-iodonium triflate, diphenyl-iodonium perfluorobutanesulfonate, diphenyl-iodonium perfluoroctanesulfonate., diphenyl-iodonium o-trifluoromethylbenzenesulfonate, diphenyl-iodonium camphorsulfonate, diphenyl-iodonium perfluorobenzenesulfonate, diphenyl-iodonium p-toluenesulfonate. U.S. Pat. No. 6,803,169 describes the use combinations of a variety of PAGs.

In some embodiments of the invention, the PAG is active at a wavelength of about 193 nm or shorter. In some embodiments, the PAG is active at a wavelength of about 193 nm. In some embodiments, the PAG is active at a wavelength of about 13.5 nm.

### Syntheses

In general, compounds per se or for use in accordance with embodiments of present invention may be prepared by the methods illustrated in the general reaction schemes as, for example, described below, or by modifications thereof, using readily available starting materials, reagents and conventional synthesis procedures. In these reactions, it is also possible to make use of variants that are in themselves known, but are not mentioned here.

### EXAMPLES

### Synthesis of: 1,1,1-trifluoro-4-methylpent-4-en-2-yl 2,3,4,5,6-pentafluoro-benzenesulfonate (29OG)

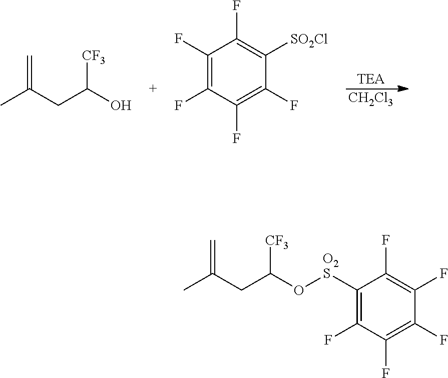

1,1,1-Trifluoro-4-methylpent-4-en-2-ol (0.355 g, 2.3 mmol) and triethylamine (0.23 g, 2.3 mmol) were weighed into a 25 mL single-neck flask equipped with a stir bar. The flask was sealed with a rubber septum and purged with nitrogen. Dichloromethane (10 mL) was added to the flask followed by pentafluorobenzenesulfonyl chloride (0.52 g, 1.95 mmol). The solution was stirred for 5 hours at room temperature. The solution was diluted with dichloromethane (25 mL) and washed with hydrochloric acid (1 M, 3×20 mL), saturated sodium bicarbonate (20 mL) and saturated sodium chloride (20 mL). The organics were dried over sodium sulfate and concentrated to give an oil. The crude product was purified by column chromatography using neutral alumina as the stationary phase and eluted with 90% hexane/10% ethyl acetate to give the desired product (0.535 g, 1.39 mmol, 70%). ¹H NMR (400 MHz, CDCl₃) δ 5.14 (m, 1H), 4.86 (m, 2H), 2.55 (m, 2H), 1.77 (s, 3H). ¹⁹F NMR (400 MHz, CDCl₃/C₆F₆) δ −79.7 (d, 3H), −136.7 (m, 2H), −145.5 (t of t, 1H), −160.9 (m, 2H).

### Synthesis of: 1,1,1-trifluoro-4-methylpent-4-en-2-yl trifluoromethanesulfonate (29OC)

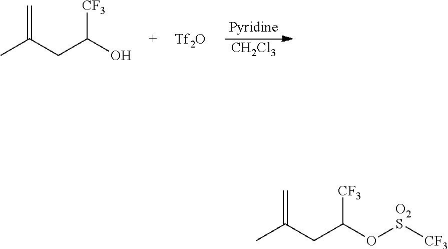

1,1,1-Trifluoro-4-methylpent-4-en-2-ol (0.30 g, 2 mmol) and pyridine (0.33 g, 4.2 mmol) were weighed into a 25 mL single-neck flask equipped with a stir bar. The flask was sealed with a rubber septum and purged with nitrogen. Dichloromethane (6 mL) was added to the flask and the solution was cooled to −40° C. A solution of trifluoromethanesulfonic anhydride (0.645 g, 2.3 mmol) in 3 mL of dichloromethane was added dropwise to the reaction flask [22]. The solution was stirred for 1 hour at −40° C. The solution was diluted with dichloromethane (10 mL) and washed with saturated sodium chloride (2×20 mL). A small amount (<0.001 g) of polyvinyl pyridine was added to the organic phase and the dichloromethane was removed under reduced pressure [23]. The crude product was purified by column chromatography using silica as the stationary phase and eluted with 80% pentane/20% ethyl formate. Polyvinyl pyridine (<0.001 g) was added to the organics and the product was concentrated under reduced pressure. The desired product was obtained as a colorless liquid (0.30 g, 1 mmol, 50%). ¹H NMR (400 MHz, CDCl₃) δ 5.07 (m, 3H), 5.61 (m, 2H), 1.79 (s, 3H).

### Synthesis of: 1,1,1-trifluoro-4-methylpent-4-en-2-yl 1,1,2,2,3,3,4,4,4-nonafluoro-butane-1-sulfonate (29OE)

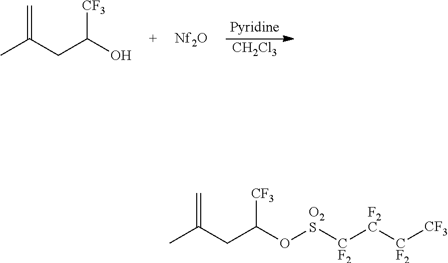

1,1,1-Trifluoro-4-methylpent-4-en-2-ol (0.15 g, 1 mmol) and pyridine (0.16 g, 2 mmol) were weighed into a 25 mL single-neck flask equipped with a stir bar. The flask was sealed with a rubber septum and purged with nitrogen. Dichloromethane (10 mL) was added to the flask and the solution was cooled to −40° C. A solution of 1,1,2,2,3,3,4,4,4-nonafluorobutane-1-sulfonic anhydride (0.62 g, 1 mmol) in dichloromethane (4 mL) was added dropwise to the reaction flask. The solution was stirred for 1 hour at −40° C. over which time a precipitate formed and the solution color turned red. The solution was stirred overnight at room temperature. The reaction was quenched with saturated sodium chloride (25 mL) and the organics were extracted with dichloromethane (4×25 mL). The organics were concentrated and the crude product was purified on a silica prep-TLC plate by eluting with 90% hexane/10% ethyl acetate. The desired product was obtained as a colorless liquid (0.036 g, 0.08 mmol, 8%). ¹H NMR (400 MHz, CDCl₃) δ 5.12 (m, 1H), 5.04 (broad s, 1H), 4.96 (broad s, 1H), 2.61 (m, 2H), 1.79 (s, 3H).

### Synthesis of Acid Precursor (Polymer Bound Type)

### 1,1-difluoro-2-oxo-2-(4-vinylphenylamino)ethanesulfonyl fluoride

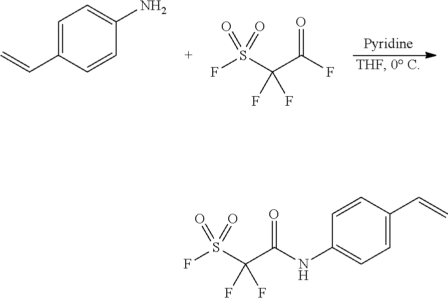

4-Aminostyrene (2.60 g, 22.2 mmol) and pyridine (1.84 g, 23.3 mmol) and THF (20 ml) were placed into a round bottom flask that was purged with nitrogen. 2,2-Difluorosulfonylacetyl fluoride (4.00 g, 22.2 mmol) dissolved THF (10 mL) was added dropwise to the flask at 0° C. and the solution was stirred for 2 hours. The reaction mixture was diluted with ethyl acetate (30 mL) and washed with 1M HCl (30 mL) and sat. NaHCO₃ aq. (30 mL) and brine (30 mL). The organics were dried with Na₂SO₄ and the solvent was concentrated under reduced pressure. The crude product was purified by column chromatography with ethyl acetate and acetone in hexane to give the product (4.97 g, 80%). ¹H NMR (400 MHz, CDCl₃) δ 8.16 (s, 1H), 7.55 (d, J=8.5, 2H), 7.45 (d, J=8.5, 2H), 6.69 (dd, J=17.6, 10.9, 1H), 5.76 (d, J=17.6, 1H), 5.30 (d, J=10.9, 1H). ¹⁹F NMR (376 MHz, CDCl₃) δ 38.52 (t, J=4.8, 1 F), −107.93 (d, J=4.7, 2 F).

### Synthesis of Acid Precursor (Polymer Blend Type)

### 1,1-difluoro-2-oxo-2-(phenylamino)ethanesulfonyl fluoride

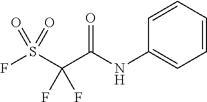 [SMILES: O=C(Nc1ccccc1)C(F)(F)S(=O)(=O)F]

¹H NMR (400 MHz, Acetone) δ 10.70 (s, 1H), 7.73 (dd, J=7.7, 1.1, 2H), 7.44 (t, J=8.0, 2H), 7.29 (t, J=7.5, 1H). ¹⁹F NMR (376 MHz, Acetone) δ 36.54 (dd, J=9.5, 4.8, 1 F), −106.99 (dd, J=22.1, 5.1, 2 F).

### Synthesis of Acid Amplifier Body

### 1,1,1-Trifluoro-3-(2-methyl-1,3-dioxan-2-yl)propan-2-ol

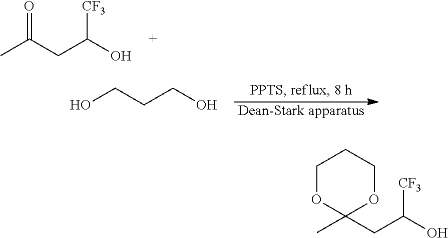

5,5,5-Trifluoro-4-hydroxy-2-pentan (6.00 g, 38.4 mmol), 1,3-propanediol (4.39 g, 57.6 mmol), pyridinium p-toluenesulfonate (PPTS) (0.965 g, 3.8 mmol) and benzene (50 mL) were weight into a 50 mL single necked round bottom flask equipped with Dean-Stark apparatus. The solution was refluxed for 8 hours. The reaction mixture was washed with sat. NaHCO3 aq. (20 mL) and brine (20 mL) and the organic layer was dried with Na₂SO₄. The solution was concentrated under reduced pressure and the resulting mixture was purified by silica gel chromatography to afford the product (6.02 g, 73%). ¹H NMR (400 MHz, CDCl₃) δ 4.50 (m, 1H), 4.25 (s, 1H), 4.10-3.83 (m, 4H), 2.09-1.86 (m, 3H), 1.53 (s, 3H), 1.44 (m, 1H).

### Synthesis of Acid Amplifier Body

### 2,2,2-Trifluoro-1-(6,10-dioxaspiro[4.5]decan-1-yl)ethanol

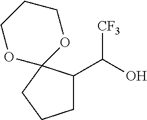 [SMILES: OC(C1CCCC12OCCCO2)C(F)(F)F]

¹H NMR (400 MHz, CDCl₃) δ 4.57-4.15 (m, 1H), 4.03-3.79 (m, 4H), 3.56 (s, 1H), 2.40-2.16 (m, 1H), 2.14-2.00 (m, 2H), 1.98-1.45 (m, 5H), 1.39 (m, 1H).

### 1-1. Synthesis of Acid Amplifier Monomer (Polymer Bound Type)

### 2,2,2-trifluoro-1-(6,10-dioxaspiro[4.5]decan-1-yl)ethyl 1,1-difluoro-2-oxo-2-(4-vinylphenylamino)ethanesulfonate

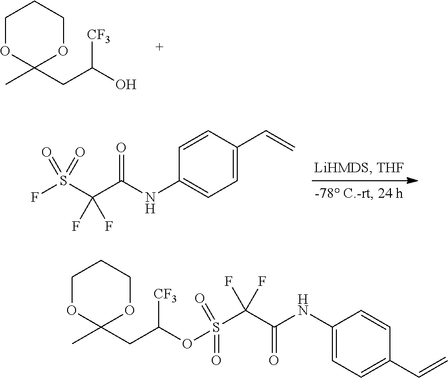

1,1,1-Trifluoro-3-(2-methyl-1,3-dioxan-2-yl)propan-2-ol (0.862 g, 4.03 mmol) and THF (5 mL) were added to a 50 mL two neck flask that had been purged with nitrogen. The flask was cooled to −78° C. 1 M Lithium hexamethyldisilazide (LiHMDS) in THF (4.4 ml, 4.4 mmol) was added dropwise to the flask and stirred for 20 minutes at −78° C. 1,1-difluoro-2-oxo-2-(4-vinylphenylamino)ethanesulfonyl fluoride (0.960 g, 3.5 mmol) dissolved in THF (5 mL) was added dropwise to the flask and the solution was stirred for 24 hours during which time the solution reached room temperature. The reaction mixture was quenched with 1M HCl (15 mL) and diluted with ethyl acetate (30 mL). The organic layer was washed with sat. NaHCO₃ aq. (15 mL) and brine (15 mL). Then the organic layer was dried with Na₂SO₄ and the solvent was removed under reduced pressure. The crude product was purified by column chromatography with ethyl acetate in hexane to give the product (1.253 g, 76%). ¹H NMR (400 MHz, DMSO) δ 11.23 (s, 1H), 7.66 (d, J=8.4, 2H), 7.50 (d, J=8.5, 2H), 6.70 (dd, J=17.6, 11.0, 1H), 5.80 (d, J=17.7, 1H), 5.65 (m, 1H), 5.24 (d, J=11.0, 1H), 4.08-3.60 (m, 4H), 2.28 (dd, J=15.7, 8.0, 1H), 2.13 (d, J=15.6, 1H), 1.86 (m, 1H), 1.43 (s, 3H), 1.35 (d, J=13.1, 1H).

### 1-2. 2,2,2-trifluoro-1-(6,10-dioxaspiro[4.5]decan-1-yl)ethyl 1,1-difluoro-2-oxo-2-(4-vinylphenylamino)ethanesulfonate

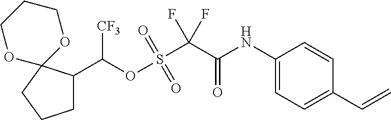 [SMILES: C=Cc1ccc(NC(=O)C(F)(F)S(=O)(=O)OC(C2CCCC23OCCCO3)C(F)(F)F)cc1]

¹H NMR (400 MHz, DMSO) δ 11.24 (s, 1H), 7.63 (s, 2H), 7.50 (d, J=7.9, 2H), 6.70 (m, 1H) 5.81 (d, J=17.7, 1H), 5.53 (s, 1H), 5.25 (d, J=10.8, 1H), 4.06-3.58 (m, 4H), 2.42-0.73 (m, 9H).

### 1-3,1,1,1-trifluoro-4-methylpent-4-en-2-yl 1,1-difluoro-2-oxo-2-(4-vinylphenylamino)ethanesulfonate

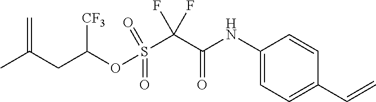 [SMILES: C=Cc1ccc(NC(=O)C(F)(F)S(=O)(=O)OC(CC(=C)C)C(F)(F)F)cc1]

¹H NMR (400 MHz, Acetone) δ 10.31 (s, 1H), 7.72 (d, J=8.6, 2H), 7.51 (d, J=8.5, 2H), 6.74 (dd, J=17.6, 11.2, 1H), 5.80 (d, J=17.7, 1H), 5.52 (m, 1H), 5.24 (d, J=11.2, 1H), 4.99 (s, 2H), 2.76 (s, 2H), 1.85 (s, 3H).

### Synthesis of Acid Amplifier Monomer (Polymer Blend Type)

### 2,2,2-trifluoro-1-(6,10-dioxaspiro[4.5]decan-1-yl)ethyl 1,1-difluoro-2-oxo-2-(phenylamino)ethanesulfonate

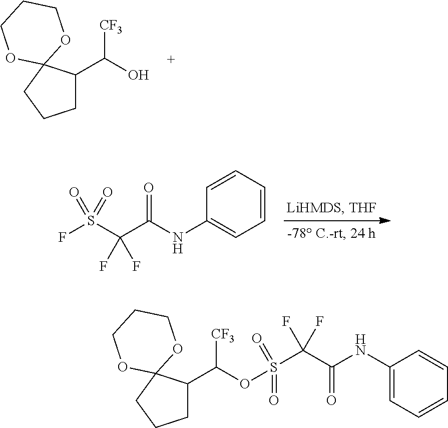

2,2,2-Trifluoro-1-(6,10-dioxaspiro[4.5]decan-1-yl)ethanol (0.398 g, 1.66 mmol) and THF (3 mL) were added to a 50 mL two neck flask that had been purged with nitrogen. The flask was cooled to −78° C. 1 M Lithium hexamethyldisilazide (LiHMDS) in THF (2.0 ml, 2.0 mmol) was added dropwise to the flask and stirred for 20 minutes at −78° C. 1,1-Difluoro-2-oxo-2-(phenylamino)ethanesulfonyl fluoride (0.400 g, 1.58 mmol) dissolved in THF (3 mL) was added dropwise to the flask and the solution was stirred for 24 hours during which time the solution reached room temperature. The reaction mixture was quenched with 1M HCl (10 mL) and diluted with ethyl acetate (20 mL). The organic layer was washed with sat. NaHCO₃ aq. (10 mL) and brine (10 mL). Then the organic layer was dried with Na₂SO₄ and the solvent was removed under reduced pressure. The crude product was purified by column chromatography with ethyl acetate in hexane to give the product (0.411 g, 56%). ¹H NMR (400 MHz, Acetone) δ=10.10 (s, 1H), 7.75 (d, J=8.0, 2H), 7.41 (t, J=7.9, 2H), 7.24 (t, J=7.4, 1H), 5.68-5.44 (m, 1H), 4.13-3.78 (m, 4H), 2.48-1.20 (m, 9H).

### 2-2,1,1,1-trifluoro-4-methylpent-4-en-2-yl 1,1-difluoro-2-oxo-2-(phenylamino)ethanesulfonate

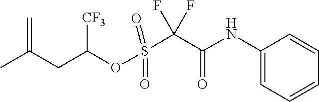 [SMILES: C=C(C)CC(OS(=O)(=O)C(F)(F)C(=O)Nc1ccccc1)C(F)(F)F]

¹H NMR (400 MHz, Acetone) δ=10.32 (s, 1H), 7.74 (d, J=7.8, 2H), 7.42 (t, J=8.0, 2H), 7.25 (t, J=7.4, 1H), 5.53 (m, 1H), 4.99 (s, 2H), 2.77 (s, 2H), 1.87 (s, 3H).

### 1,1,1-trifluoro-3-(2-methyl-1,3-dioxan-2-yl)propan-2-yl 1,1-difluoro-2-oxo-2-(phenylamino)ethanesulfonate

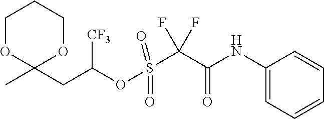 [SMILES: CC1(CC(OS(=O)(=O)C(F)(F)C(=O)Nc2ccccc2)C(F)(F)F)OCCCO1]

¹H NMR (400 MHz, Acetone) δ=10.09 (s, 1H), 7.74 (d, J=7.8, 2H), 7.41 (t, J=8.0, 2H), 7.24 (t, J=7.4, 1H), 5.71 (m, 1H), 4.14-3.71 (m, 4H), 2.27 (dd, J=15.8, 7.6, 1H), 2.17 (d, J=16.0, 1H), 2.04 (m, 1H), 1.51 (s, 3H), 1.39 (d, J=13.3, 1H).

### Synthesis of Polymer Bound Acid Amplifier

A general methodology for preparing polymerizing ketal-trigger stabilized acid amplifiers into polymer chains useful for EUV lithography is shown below:

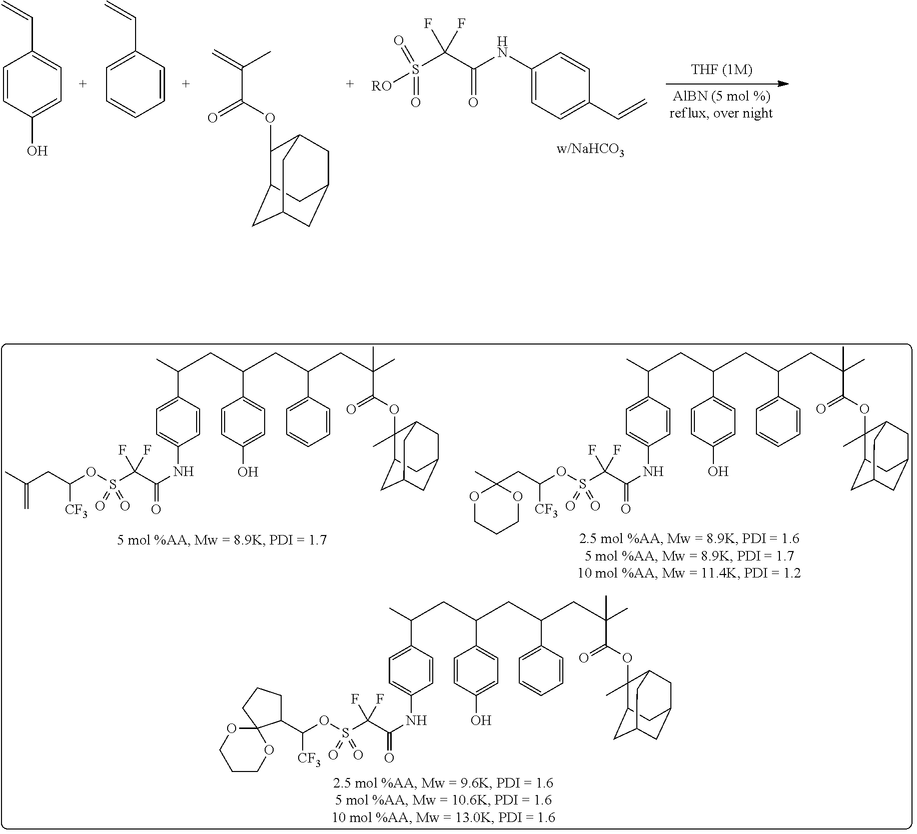

One specific example of such a polymer synthesis is described below:

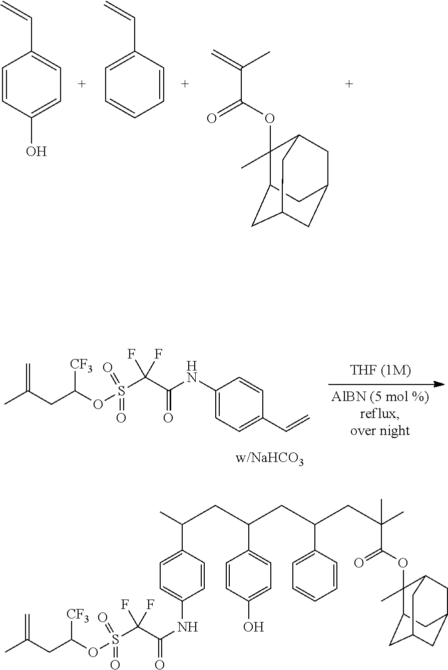

Hydroxystyrene (0.684 g, 5.7 mmol), styrene (0.197 g, 1.9 mmol), 2-methyl-2-adamntyl methacrylate (0.445 g, 1.9 mmol), 1,1,1-trifluoro-4-methylpent-4-en-2-yl 1,1-difluoro-2-oxo-2-(4-vinylphenylamino)ethanesulfonate (0.206 g, 0.5 mmol), NaHCO₃ (63 mg, 0.75 mmol) and THF (8 mL) were added to a 50 mL two-neck flask and degassed with nitrogen for 15 minutes. The radical initiator 2,2′-azobis-(2-methylbutynitril) (AIBN) (82 mg, 0.5 mmol) was weighed into a flask and dissolved in THF (2 mL). AIBN solution was added to the monomer solution and the reaction mixture was refluxed for 24 hours. After over night reflux, the THF was removed under reduced pressure and the remaining polymer was dissolved in MeOH. The polymer solution was dripped into a beaker of water (150 mL). The precipitated polymer was filtered and dried to the give desired product (1.171 g, 76%)

### Results

Two Generation-3 AAs, 29OG and 29OC, were tested. These compounds were characterized with our thermal stability measurements and ¹⁹F NMR kinetic measurements, and the additive effects of 29OG were evaluated in our OS2 resist formulation. The “open source” OS2 resist formulation is composed of 15 wt % of solids of di(4-tert-butylphenyl) iodonium perfluoro-1-butane-sulfonate photoacid generator (PAG), 1.5 wt % of solids of tetrabutylammonium hydroxide base, 4-hydroxystyrene/styrene/t-butyl acrylate (65/15/20) polymer, and a 50/50 mixture of ethyl lactate and propylene glycol methyl ether acetate.

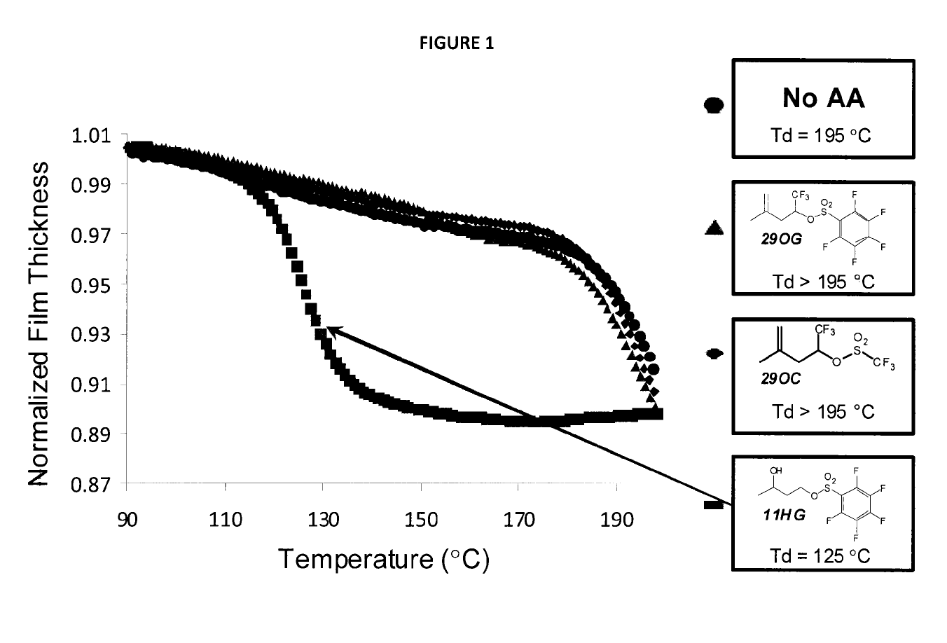

FIG. 1 shows the thermally-programmed spectroscopic analysis of OS2 resist and OS2 with 70 mM added 29OG, 29OC or 11HG. Resist films of 70 nm were coated on silicon substrates and soft baked at 90° C. for 60 s. The film thickness was measured as a function of temperature at a temperature ramp rate of 10° C./min. The steepest part of the curve indicates the decomposition temperature. The OS2 ESCAP polymer decomposed at 195° C. A thermally stable Generation-2 AA with a pentafluorobenzene sulfonate acid precursor (11HG) has a decomposition temperature of 125° C. Remarkably, resists with 29OG and 29OC have the same film thickness curve as the control OS2 resist. These AAs decompose at a temperature higher than the ESCAP polymer.

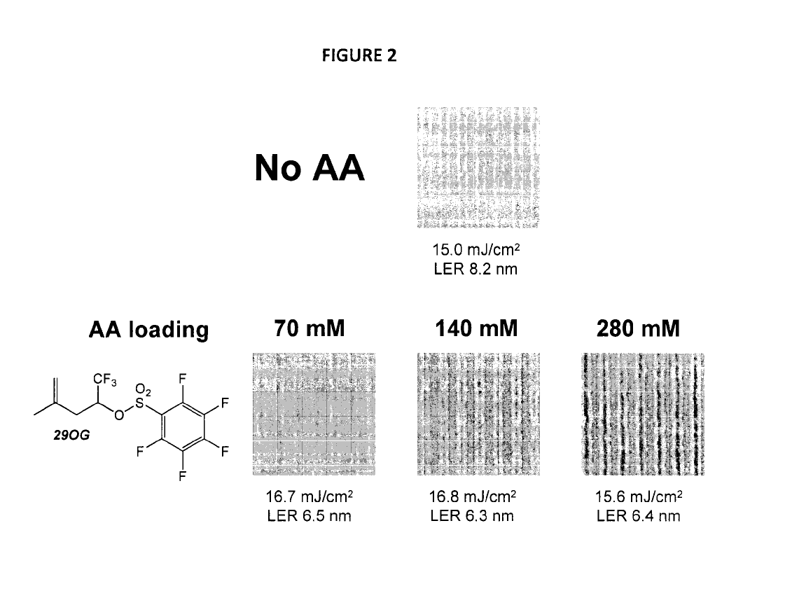

FIG. 2 shows 50 nm L/S imaging results of OS2 resist with 0, 70, 140 or 280 mM added 29OG. The resist films were coated to 60 nm thickness and soft baked at 110° C. for 60 s. The films were exposed to EUV radiation on the micro exposure tool with annular illumination, post exposed baked at 130° C. for 90 s and developed in Tetramethylammonium Hydroxide for 45 s. The sizing dose for OS2 is 15.0 mJ·cm⁻² and 16.7, 16.8 and 15.6 mJ·cm⁻² for resist with 70, 140 and 280 mM 29OG respectively. While 29OG does not appear to improve the resist sensitivity, it does improve line edge roughness (LER) from 8.2±0.5 nm (OS2) to 6.4±0.5 nm.

The thermal decomposition kinetics of the AAs were measured using ¹⁹F NMR. Solutions of AAs (70 mM) in 50/50 wt % C₆D₆/m-ethylphenol in the presence and absence of 1.2 eq. of added 2,4,6-tri-t-butylpyridine were monitored. The rate constants were measured at 145° C.

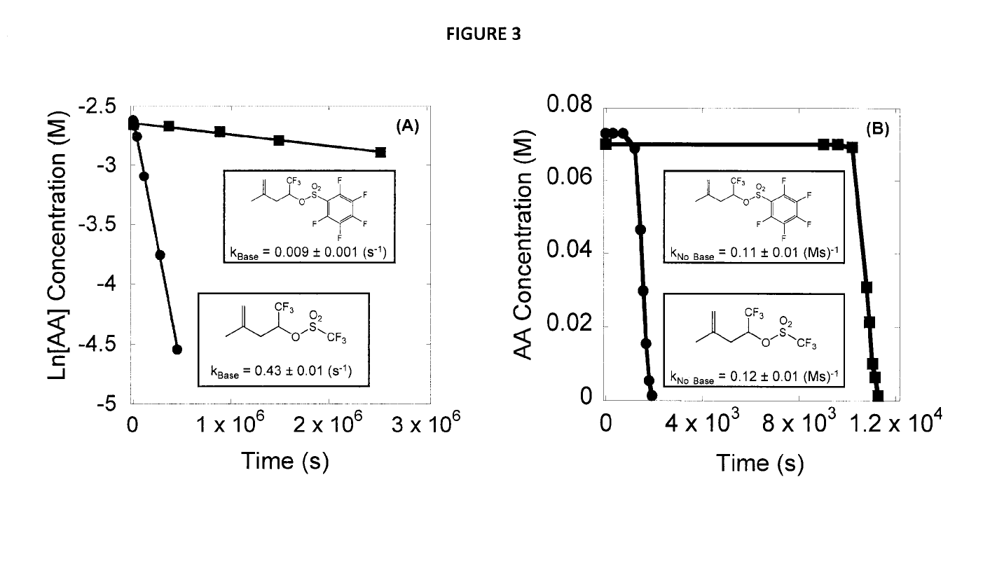

FIG. 3 shows the decomposition kinetics of 29OG and 29OC in the presence (FIG. 3A) and absence (FIG. 3B) of added base. FIG. 3A shows the thermal (uncatalyzed) decomposition of 29OG and 29OC. The natural log of AA concentration versus time yields the rate constants for 29OG and 29OG to be 0.009×10⁻⁵ s⁻¹ and 0.43×10⁻⁵ s⁻¹ respectively. At these slow decomposition rates, 29OG decompose only 20% after heating at 145° C. for 29 days. Both compounds are more thermally stable than any Generation-2 AA that has been measured. FIG. 3B shows the decomposition of 29OG and 29OC in the absence of base. The AA concentration versus time shows the characteristic profile of autocatalytic decomposition. Initially, there is no indication of decomposition but once a small amount of acid is thermally generated, both compounds decompose rapidly over a very short time period. The autocatalytic rate constants for 29OG and 29OC are the same within experimental error, 0.11 (Ms)⁻¹ and 0.12 (Ms)⁻¹ respectively.

Table I compares uncatalyzed rate constants (k_{Base}) and ratios of autocatalytic/uncatalyzed (k_{No Base}/k_{Base}) rate constants for some active Generation-2 and Generation-3 AAs. Of the Generation-2 AAs, 3HF has the best k_{No Base}/k_{Base} ratio (at 100° C.) of 1390, 3HG has a k_{No Base}/k_{Base} ratio of 300 (at 100° C.) but is the best ratio of the AAs that generate pentafluorobenzenesulfonic acid and 11HG has a k_{No Base}/k_{Base} ratio (at 100° C.) of 1.0, but is the most thermally stable AA that generates pentafluorobenzenesulfonic acid. 6AB is also a Generation-2 AA and has the best thermal stability with a k_{Base} of 0.49×10⁻⁵ s⁻¹ and 13×10⁻⁵ s⁻¹ at 100° C. and 145° C., respectively. The k_{No Base}/k_{Base} ratio is 490 and 270 at 100° C. and 145° C., respectively. The high thermal stability and moderate k_{No Base}/k_{Base} ratio is partially due to the relatively weak fluorinated sulfonic acid precursor, 4-(trifluoromethyl)benzene sulfonate. In comparison, both Generation-3 AAs have far superior k_{Base} and k_{No Base}/k_{Base} ratios than the best Generation-2 AAs. 29OC and 29OG have a k_{Base} of 0.43×10⁻⁵ s⁻¹ and 0.009×10⁻⁵ s⁻¹ at 145° C. respectively. Even though they generate strong fluorinated sulfonic acids, pentafluorobenzene sulfonic acid and triflic acid, they are 30 and 1,400× more stable than 6AB. 29OC and 29OG also have unprecedented k_{No Base}/k_{Base} ratios of 28,000 and 1,000,000 respectively. With such promising results, Generation-3 AAs provide an opportunity to make AAs with varied characteristics.

TABLE I
k_{Base} and k_{No Base}/k_{Base} rate constants at 100° C. and 145 ° C. for selected AAs. k_{Base} units are ×10⁻⁵s⁻¹

| | Generation-2 Acid Amplifiers | | |
|---|---|---|---|
| | 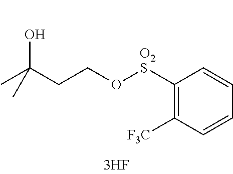 [SMILES: CC(C)(O)CCOS(=O)(=O)c1ccccc1C(F)(F)F] | 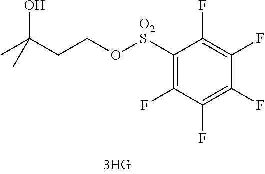 [SMILES: CC(C)(O)CCOS(=O)(=O)c1c(F)c(F)c(F)c(F)c1F] | 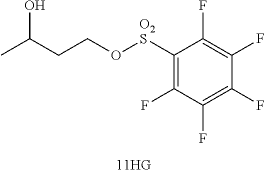 [SMILES: CC(O)CCOS(=O)(=O)c1c(F)c(F)c(F)c(F)c1F] |
| k_{Base} at | 5.1 | 73 | 33 |
| 100° C. | | | |
| (small is | | | |
| preferred) | | | |
| k_{Base} at | — | — | — |
| 145° C. | | | |
| (smaller is | | | |
| preferred) | | | |
| k_{No Base}/k_{Base} | 1390 | 300 | 1 |
| at 100° C. | | | |
| (bigger is | | | |
| preferred) | | | |
| k_{No Base}/k_{Base} | — | — | — |
| at 145° C. | | | |
| (bigger is | | | |
| preferred) | | | |
| | Generation-2 Acid Amplifiers | Generation-3 Acid Amplifiers | |
| | 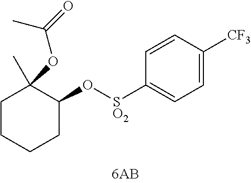 [SMILES: CC(=O)O[C@]1(C)CCCC[C@@H]1OS(=O)(=O)c1ccc(C(F)(F)F)cc1] | 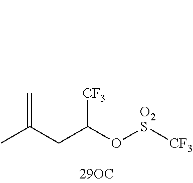 [SMILES: C=C(C)CC(OS(=O)(=O)C(F)(F)F)C(F)(F)F] | 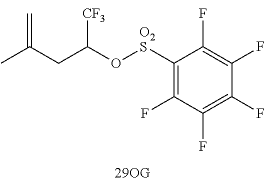 [SMILES: C=C(C)CC(OS(=O)(=O)c1c(F)c(F)c(F)c(F)c1F)C(F)(F)F] |
| k_{Base} at | 0.49 | — | — |
| 100° C. | | | |
| (small is | | | |
| preferred) | | | |
| k_{Base} at | 13 | 0.43 | 0.009 |
| 145° C. | | | |
| (smaller is | | | |
| preferred) | | | |
| k_{No Base}/k_{Base} | 490 | — | — |
| at 100° C. | | | |
| (bigger is | | | |
| preferred) | | | |
| k_{No Base}/k_{Base} | 2700 | 28,000 | 1,000,000 |
| at 145° C. | | | |
| (bigger is | | | |
| preferred) | | | |

Table II illustrates examples of formulations prepared from bound and blended Generation-4 Acid (ketal-triggered) stabilized acid amplifiers:

| | Composition of Polymer | | | | | | |
|---|---|---|---|---|---|---|---|
| Resist name | 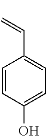 | 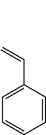 | 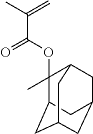 [SMILES: C=C(C)C(=O)OC1(C)C2CC3CC(C2)CC1C3] | 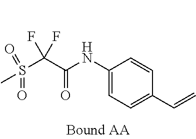 [SMILES: C=Cc1ccc(NC(=O)C(F)(F)S(C)(=O)=O)cc1] | 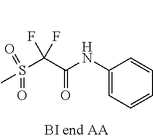 [SMILES: CS(=O)(=O)C(F)(F)C(=O)Nc1ccccc1] | PAG | Base |
| a1-kh137 | 58.5% | 19.5% | 19.5% | 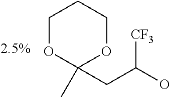 | — | 10% | 1% |
| b1-kh140 | 58.5% | 19.5% | 19.5% | 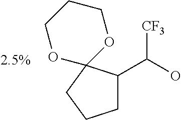 [SMILES: OC(C1CCCC12OCCCO2)C(F)(F)F] | — | 10% | 1% |
| c1-kh120 | 57% | 19% | 19% | 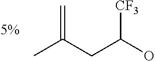 | — | 10% | 1% |
| d1-kh122 | 57% | 19% | 19% | 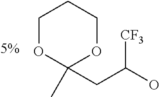 | — | 10% | 1% |
| e1-kh135 | 57% | 19% | 19% | 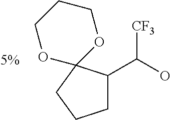 [SMILES: OC(C1CCCC12OCCCO2)C(F)(F)F] | — | 10% | 1% |
| f1-kh138 | 54% | 18% | 18% | 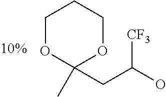 | — | 10% | 1% |
| g1-kh139 | 54% | 18% | 18% | 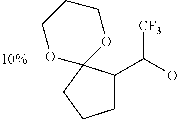 [SMILES: OC(C1CCCC12OCCCO2)C(F)(F)F] | — | 10% | 1% |
| h1-kh134 | 60% | 20% | 20% | — | — | 10% | 1% |
| i1-kh109 | 60% | 20% | 20% | — | 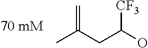 | 10% | 1% |
| j1-kh111 | 60% | 20% | 20% | — | 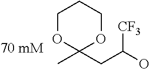 | 10% | 1% |
| k1-kh131 | 60% | 20% | 20% | — | 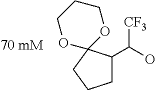 [SMILES: OC(C1CCCC12OCCCO2)C(F)(F)F] | 10% | 1% |
| l1-kh131 | 60% | 20% | 20% | — | 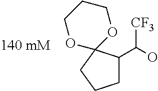 [SMILES: OC(C1CCCC12OCCCO2)C(F)(F)F] | 10% | 1% |
| m1-kh131 | 60% | 20% | 20% | — | 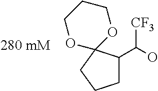 [SMILES: OC(C1CCCC12OCCCO2)C(F)(F)F] | 10% | 1% |
| OS2 | 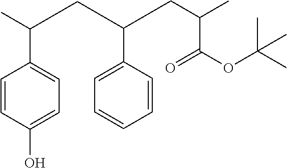 [SMILES: CC(CC(CC(C)c1ccc(O)cc1)c1ccccc1)C(=O)OC(C)(C)C] | | | — | — | 15% | 1.5% |
| a2-kh137 | 58.5% | 19.5% | 19.5% | 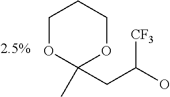 | — | 10% | 2% |
| b2-kh140 | 58.5% | 19.5% | 19.5% | 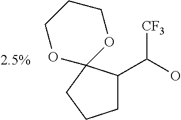 [SMILES: OC(C1CCCC12OCCCO2)C(F)(F)F] | — | 10% | 2% |
| c2-kh120 | 57% | 19% | 19% | 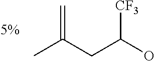 | — | 10% | 2 |
| d2-kh122 | 57% | 19% | 19% | 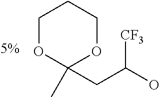 | — | 10% | 2% |
| e2-kh135 | 57% | 19% | 19% | 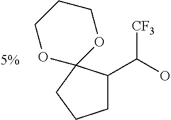 [SMILES: OC(C1CCCC12OCCCO2)C(F)(F)F] | — | 10% | 2% |
| f2-kh138 | 54% | 18% | 18% | 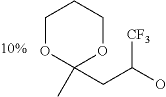 | — | 10% | 2% |
| g2-kh139 | 54% | 18% | 18% | 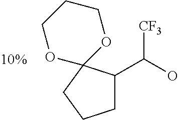 [SMILES: OC(C1CCCC12OCCCO2)C(F)(F)F] | — | 10% | 2% |
| h2-kh134 | 60% | 20% | 20% | — | — | 10% | 2% |
| i2-kh109 | 60% | 20% | 20% | — | 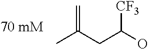 | 10% | 2% |
| j2-kh111 | 60% | 20% | 20% | — | 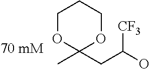 | 10% | 2% |
| k2-kh131 | 60% | 20% | 20% | — | 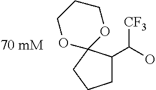 [SMILES: OC(C1CCCC12OCCCO2)C(F)(F)F] | 10% | 2% |
| l2-kh131 | 60% | 20% | 20% | — | 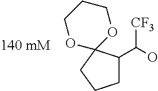 [SMILES: OC(C1CCCC12OCCCO2)C(F)(F)F] | 10% | 2% |
| m2-kh131 | 60% | 20% | 20% | — | 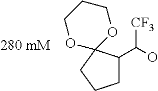 [SMILES: OC(C1CCCC12OCCCO2)C(F)(F)F] | 10% | 2% |

Skilled artisans will appreciate variations which may be employed to obtain ethers, amines, thiols, thiol ethers and the like, rather than the alcohols or acetates depicted. It will also be appreciated that the alcohols may be esterified with a polymer, such as the photoresist polymer. In some cases, it is expected that this will result in higher concentrations of the acid amplifiers in the resists than would otherwise be achievable, without significant derogation from other resist properties. Furthermore, depending on the choice of acid amplifier, attachment to the polymer may be used to affect the solubility of the polymer, i.e. to create a “solubility switch”.

The invention has been described in detail with particular reference to some embodiments thereof, but it will be understood by those skilled in the art that variations and modifications can be effected within the spirit and scope of the invention.

1. A compound of formula I 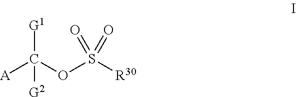
wherein
G¹ is selected from —N⁺(CH₃)₃, —(CH₂)—N⁺(CH₃)₃, —(CH₂)—NO₂, —CH₂(CN), —CH(CN)₂, —(CH₂)₀₋₁SO₂(C₁-C₈)hydrocarbon, —C₆F₅, —Si(CH₃)₃, halogen, —CᵢHⱼ(halogen)ₖ, and CₛHₜ(halogen)ᵤ-E, wherein i is 1-2, j is 0-3, k is 1-5, and the sum of j plus k is 2i+1; and wherein s is 1-2, t is 0-2, u is 1-4, and the sum of t plus u is 2s;
E is selected from —(C₁-C₆)alkyl, aryl, (C₁-C₆)haloalkyl, haloaryl, haloaryl(C₁-C₂)alkyl, and aryl(Cₜ—C₂)alkyl;
G² is selected from hydrogen, —CF₃, —N⁺(CH₃)₃, halogen and (C₁-C₁₀)hydrocarbon;
A is selected from the following moieties: 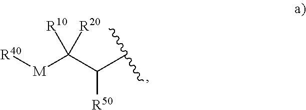
wherein
M is —O—, —S— or —NR⁹⁰—;
R¹⁰ is chosen from (C₁-C₈)saturated hydrocarbon; (C₁-C₈)saturated hydrocarbon substituted with halogen, cyano or nitro; (C₁-C₈)silaalkane; —O—(C₁-C₈)saturated hydrocarbon; —O—(C₁-C₈)saturated hydrocarbon substituted with halogen, cyano or nitro; —S—(C₁-C₈)saturated hydrocarbon; —S—(C₁-C₈)saturated hydrocarbon substituted with halogen, cyano or nitro; and optionally substituted phenyl;
R²⁰ is chosen from H, (C₁-C₆) hydrocarbon and (C₁-C₆) hydrocarbon substituted with nitro or cyano, or taken together with the carbon to which they are attached, R¹⁰ and R²⁰ form a three- to eight-membered ring;
R⁴⁰ is chosen from H, (C₁-C₆)alkyl, —C(═O)(C₁-C₆)alkyl, —C(═O)(C₁-C₆)alkenyl, —C(═O)(C₁-C₆)haloalkyl, benzyl, substituted benzyl, —C(═O)phenyl, —C(═O)substituted phenyl, —SO₂-phenyl, —SO₂(substituted)phenyl and Q; or, when M is O or S, R¹⁰ and R⁴⁰ together with the carbons to which they are attached form a four- to eight-membered ring optionally substituted with one or more (C₁-C₆) hydrocarbon groups;
R⁵⁰ is chosen from H, (C₁-C₆) hydrocarbon, nitro, cyano, (C₁-C₆) hydrocarbon substituted with nitro or cyano, and (C₁-C₆)silaalkane, or together with the carbons to which they are attached, R¹⁰ and R⁵⁰ form a (C₃-C₈) hydrocarbon ring; or, when M is O or S, R²⁰ and R⁵⁰ together with the carbons to which they are attached form a three- to eight-membered ring optionally substituted with one or more (C₁-C₆) hydrocarbon groups;
R⁹⁰ is chosen from H, (C₁-C₆)alkyl, —C(═O)(C₁-C₆)alkyl and phenyl, or together with the nitrogen to which they are attached, R⁴⁰ and R⁹⁰ may form a nitrogen heterocycle, with the proviso that one of R⁴⁰ and R⁹⁰ must be an acyl, and when R⁴⁰ and R⁹⁰ together with the nitrogen to which they are attached form a heterocycle, the heterocyle must contain one or two α-oxo substituents; and 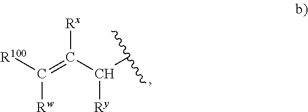
wherein
R^{w}, R^{x} and R^{y} are chosen independently in each instance from hydrogen, (C₁-C₁₀) hydrocarbon and (C₁-C₈) silaalkane;
R¹⁰⁰ is chosen from hydrogen and (C₁-C₂₀) hydrocarbon; or
any two of R¹⁰⁰, R^{w}, R^{x}, R^{y} and G², taken together with the carbons to which they are attached, form a (C₅-C₈) hydrocarbon ring which may be substituted with (C₁-C₈)hydrocarbon, with the proviso that the C═C double bond above is not contained within a phenyl ring; or
G¹ and A, together with the carbon to which they are attached, can form a non-aromatic, 5- or 6-membered ring D: 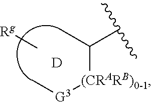
wherein R^{g} represents one or two substituents independently selected in each instance from hydrogen, -M-R⁴⁰, (C₁-C₁₀)hydrocarbon, hydroxyl and R^{h}CH₂COO—, wherein R^{h} is chosen from halogen, hydroxyl, a polymer and an oligomer; and wherein G³ is selected from —N⁺(CH₃)₂, —(CH)—NO₂, —CH(CN), —C(CN)₂, —Si(CH₃)₂—, —CᵢHⱼ(halogen)ₖ, and CₛHₜ(halogen)ᵤ-E, wherein i is 1-2, j is 0-3, k is 1-5, and the sum of j plus k is 2i; and wherein s is 1-2, t is 0-2, u is 1-4, and the sum of t plus u is 2s minus 1; and wherein R^{A} and R^{B} can each be selected independently from hydrogen, (C₁-C₆)alkyl and benzyl;
R³⁰ is chosen from
(a) —CₙHₘFₚ wherein n is 1-8, m is 0-16, p is 1-17 and the sum of m plus p is 2n+1;
(b) —CH₂C(═O)-Q;
(c) —CF₂CH₂OQ;
(d) —CF₂C(═O)-Q;
(e) —CF₂CH₂C(═O)—R³¹, wherein R³¹ is selected from CH═CH₂, CCH₃═CH₂, CHQCH₂Q and CCH₃QCH₂Q; 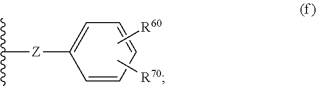
wherein Z is a direct bond, CH₂, CHF or CF₂;
R⁶⁰ is chosen from —CF₃, —OCH₃, —NO₂, F, Cl, Br, —CH₂Br, —CH═CH₂, —OCH₂CH₂Br, -Q, —O-Q, —OCH₂CH₂-Q, —OCH₂CH₂O-Q, —CH(O)CH₂-Q, —OC═OCH═CH₂, —OC═OCCH₃═CH₂, —OC═OCHQCH₂Q, and —OC═OCCH₃QCH₂Q;
R⁷⁰ represents from one to four substituents chosen independently in each instance from H, —CF₃, —OCH₃, —CH₃, —NO₂, F, Br, Cl, —CᵢHⱼ(halogen)ₖ, and CₛHₜ(halogen)ᵤ-E, wherein i is 1-2, j is 0-3, k is 1-5, and the sum of j plus k is 2i+1; and wherein s is 1-2, t is 0-2, u is 1-4, and the sum of t plus u is 2s;
E is selected from —(C₁-C₆)alkyl, aryl, (C₁-C₆)haloalkyl, haloaryl, haloaryl(C₁-C₂)alkyl, and aryl(C₁-C₂)alkyl;
(g) —(CH₂)_{q}Cl, wherein q is an integer from 1 to 8;
(h) —CF₂C(═O)NHC₆H₄R⁶⁰;
(i) —CH₂C(═O)NHC₆H₄R⁶⁰; and
(j) —CHFC(═O)NHC₆H₄R⁶⁰;
and
Q is a polymer or oligomer.

2. A compound according to claim 1 wherein A is

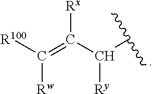

3. A compound according to claim 2 wherein R¹⁰⁰, R^{w}, R^{x}, R^{y} and G² are chosen independently in each instance from hydrogen, (C₁-C₁₀)alkyl, (C₂-C₁₀)alkenyl, and a saturated or unsaturated cyclic (C₄-C₈)hydrocarbon optionally linked by a methylene.

4-10. (canceled)

11. A compound according to claim 1 wherein A is

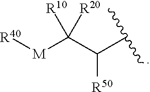

12. A compound according to claim 11 wherein
R¹⁰ is chosen from methyl, propenyl, propynyl, dimethylbutynyl, cyclopropyl, trimethylsilylmethyl, phenyl, nitrophenyl, nitromethyl and cyanomethyl; and
R²⁰ is chosen from H and methyl.

13-14. (canceled)

15. A compound according to claim 1 wherein R¹⁰ and R⁵⁰ taken together form a cyclopentyl or cyclohexyl ring.

16. A compound according to claim 11 wherein M is oxygen.

17. A compound according to claim 16 wherein R⁴⁰ is chosen from H, methyl, ethyl, isopropyl, t-butyl, benzyl, acetyl, chloroacetyl, dichloroacetyl, trichloroacetyl, benzoyl, 4-(trifluoromethyl)benzoyl, 4-nitrobenzoyl, 4-carboxybenzoyl, 4-methoxybenzoyl, benzenesulfonyl, 4-(trifluoromethyl)benzenesulfonyl, 4-nitrobenzenesulfonyl, 4-carboxybenzenesulfonyl and 4-methoxybenzenesulfonyl.

18-22. (canceled)

23. A compound according to claim 1 wherein G¹ and A, together with the carbon to which they are attached, form a non-aromatic, 5- or 6-membered ring D:

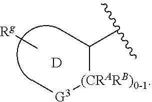

24-32. (canceled)

33. A compound according to claim 1 wherein R³⁰ is selected from

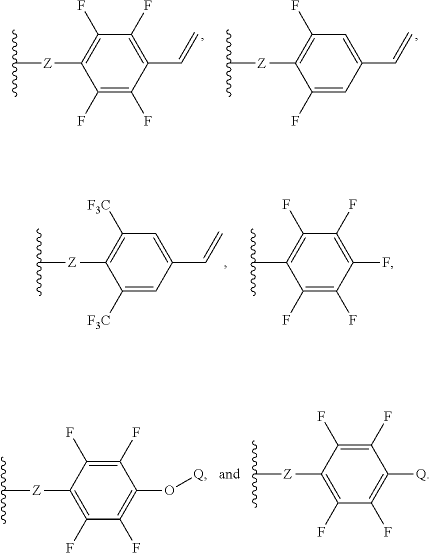

34-37. (canceled)

38. A compound of formula 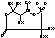
wherein
G¹ is selected from —N⁺(CH₃)₃, —(CH₂)—N⁺(CH₃)₃, —(CH₂)—NO₂, —CH₂(CN), —CH(CN)₂, —(CH₂)₀₋₁SO₂(C₁-C₈)hydrocarbon, —C₆F₅, —Si(CH₃)₃, halogen, —CᵢHⱼ(halogen)ₖ, and CₛHₜ(halogen)ᵤ-E, wherein i is 1-2, j is 0-3, k is 1-5, and the sum of j plus k is 2i+1; and wherein s is 1-2, t is 0-2, u is 1-4, and the sum of t plus u is 2s;
E is selected from —(C₁-C₆)alkyl, aryl, (C₁-C₆)haloalkyl, haloaryl, haloaryl(C₁-C₂)alkyl, and aryl(C₁-C₂)alkyl;
R¹⁰ is chosen from (C₁-C₈)saturated hydrocarbon; (C₁-C₈)saturated hydrocarbon substituted with halogen, cyano or nitro; (C₁-C₈)silaalkane and optionally substituted phenyl;
R²⁰ is chosen from H, (C₁-C₆) hydrocarbon and (C₁-C₆) hydrocarbon substituted with nitro or cyano, or taken together with the carbon to which they are attached, R¹⁰ and R²⁰ form a (C₃-C₈) hydrocarbon ring;
R⁵⁰ is chosen from H, (C₁-C₆) hydrocarbon, nitro, cyano, (C₁-C₆) hydrocarbon substituted with nitro or cyano, and (C₁-C₆)silaalkane, or together with the carbons to which they are attached, R¹⁰ and R⁵⁰ form a (C₃-C₈) hydrocarbon ring;
R^{30a} is chosen from H, F and (C₁-C₆) hydrocarbon; and
R^{30b} is chosen from H and F.

39. A compound according to claim 1 of formula 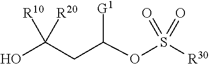
wherein
R¹⁰ is (C₁-C₈)saturated hydrocarbon;
R²⁰ is chosen from H and (C₁-C₆) hydrocarbon;
G¹ is selected from —N⁺(CH₃)₃, —(CH₂)—N⁺(CH₃)₃, —(CH₂)—NO₂, —CH₂(CN), —CH(CN)₂, —(CH₂)₀₋₁SO₂(C₁-C₈)hydrocarbon, —C₆F₅, —Si(CH₃)₃, halogen, —CᵢHⱼ(halogen)ₖ, and CₛHₜ(halogen)ᵤ-E, wherein i is 1-2, j is 0-3, k is 1-5, and the sum of j plus k is 2i+1; and wherein s is 1-2, t is 0-2, u is 1-4, and the sum of t plus u is 2s;
E is selected from —(C₁-C₆)alkyl, aryl, (C₁-C₆)haloalkyl, haloaryl, haloaryl(C₁-C₂)alkyl, and aryl(C₁-C₂)alkyl.

40. (canceled)

41. A compound according to claim 1 selected from the group consisting of 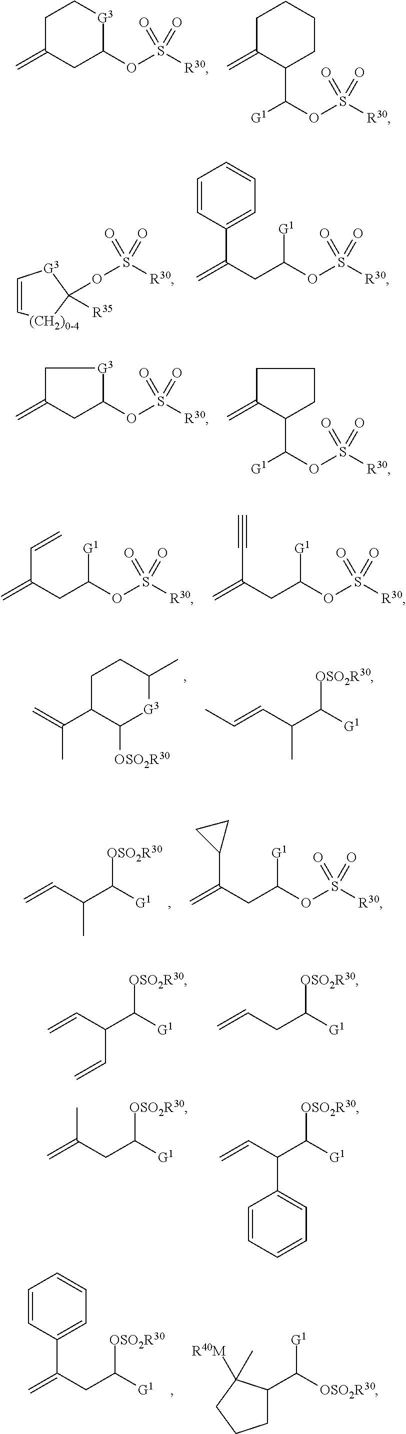 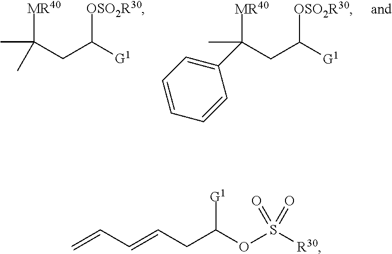
wherein R³⁵ is selected from hydrogen, (C₁-C₆)alkyl and benzyl.

42. A compound according to claim 1 wherein G¹ is —CF₃ and R³⁰ is

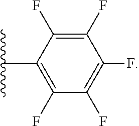 [SMILES: *c1c(F)c(F)c(F)c(F)c1F]

43. A compound according to claim 42 selected from the group consisting of

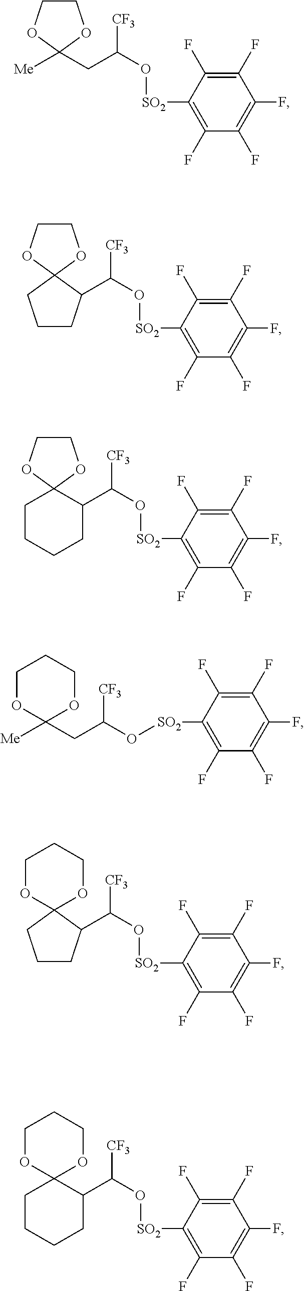 [SMILES: CC1(CC(OS(=O)(=O)c2c(F)c(F)c(F)c(F)c2F)C(F)(F)F)OCCO1 ; O=S(=O)(OC(C1CCCC12OCCO2)C(F)(F)F)c1c(F)c(F)c(F)c(F)c1F ; O=S(=O)(OC(C1CCCCC12OCCO2)C(F)(F)F)c1c(F)c(F)c(F)c(F)c1F ; CC1(CC(OS(=O)(=O)c2c(F)c(F)c(F)c(F)c2F)C(F)(F)F)OCCCO1 ; O=S(=O)(OC(C1CCCC12OCCCO2)C(F)(F)F)c1c(F)c(F)c(F)c(F)c1F ; O=S(=O)(OC(C1CCCCC12OCCCO2)C(F)(F)F)c1c(F)c(F)c(F)c(F)c1F]

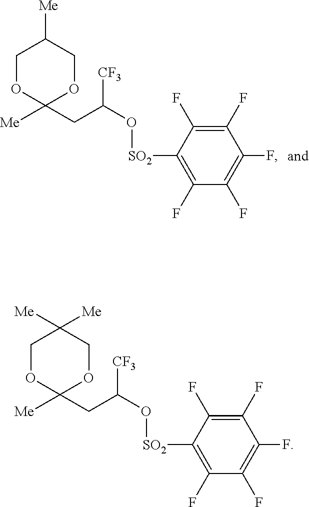 [SMILES: CC1COC(C)(CC(OS(=O)(=O)c2c(F)c(F)c(F)c(F)c2F)C(F)(F)F)OC1 ; CC1(C)COC(C)(CC(OS(=O)(=O)c2c(F)c(F)c(F)c(F)c2F)C(F)(F)F)OC1]

44-46. (canceled)

47. A composition for photolithography comprising:
(a) a photolithographic polymer; and
(b) a compound according to claim 1.

48. A photoresist composition comprising:
(a) a photoresist polymer; and
(b) a compound according to claim 1.

49. A photoresist substrate which is coated with a photoresist composition according to claim 48.

50. A method for preparing a substrate for photolithography, comprising coating said substrate with a composition according to claim 48.

51. A method for conducting photolithography on a substrate, comprising (a) providing a substrate, (b) coating said substrate with a composition according to claim 48, and (c) irradiating the coated substrate through a photomask.

52. (canceled)
